(19) United States
(12) Patent Application Publication
(10) Pub. No.: US 2012/0020158 A1
(43) Pub. Date: Jan. 26, 2012

(54) SEMICONDUCTOR MEMORY DEVICE AND MANUFACTURING METHOD THEREOF

(75) Inventors: Tohru OZAKI, Tokyo (JP); Mitsuhiro Noguchi, Yokohama-shi (JP); Hideaki Maekawa, Yokohama-shi (JP); Hiromitsu Mashita, Yokohama-shi (JP); Takafumi Taguchi, Yokohama-shi (JP); Kazuhito Kobayashi, Chigasaki-shi (JP); Hidefumi Mukai, Mie-gun (JP); Hiroyuki Nitta, Yokkaichi-shi (JP)

(73) Assignee: KABUSHIKI KAISHA TOSHIBA, Tokyo (JP)

(21) Appl. No.: 13/187,000

(22) Filed: Jul. 20, 2011

(30) Foreign Application Priority Data
Jul. 21, 2010 (JP) 2010-164253

(51) Int. Cl. G11C 16/04; H01L 21/78

(52) U.S. Cl. 365/185.05; 438/462; 257/E21.599

(57) ABSTRACT

A memory cell array includes memory strings arranged in a first direction. Word-lines and select gate lines extend in a second direction perpendicular to the first direction. The select gate line also extends in the second direction. The word-lines have a first line width in the first direction and arranged with a first distance therebetween. The select gate line includes a first interconnection in the first direction, the first interconnection having a second line width larger than the first line width, and a second interconnection extending from an end portion of the first interconnection, the second interconnection having a third line width the same as the first line width. A first word-line adjacent to the select gate line is arranged having a second distance to the second interconnection, the second distance being (4N+1) times the first distance (N being an integer of 1 or more).

### CROSS REFERENCE TO RELATED APPLICATIONS

This application is based on and claims the benefit of priority from prior Japanese Patent Application No. 2010-164253, filed on Jul. 21, 2010, the entire contents of which are incorporated herein by reference.

### FIELD

Embodiments described herein relate to a semiconductor memory device and a manufacturing method thereof.

### BACKGROUND

As the NAND flash memory has recently become smaller and highly integrated, a manufacturing technology is proposed in which various interconnections of the NAND flash memory are formed using the so-called sidewall transfer process that may provide an interconnection width smaller than the lithography resolution limit.

The sidewall transfer process is carried out in the procedure described below. First, a first hard mask is formed having a line-and-space pattern of the lithography resolution limit. Then, the first hard mask is thinned (slimmed) by a process such as wet etching, and a sidewall film as a second hard mask is formed on the sidewall of the slimmed first hard mask.

Then, the first hard mask is removed by anisotropic etching, and the remaining sidewall film as the second hard mask is used as a mask to etch the underlying material film. An interconnection may thus be formed having a line width and a line pitch smaller than the lithography resolution limit.

Even if the sidewall transfer process is used, however, some interconnections are formed as having a width equal to or greater than the lithography resolution limit, including a selection gate interconnection of a select transistor and a contact fringe interconnection for making a contact. Interconnections having such a large width are formed by any other process different from the sidewall transfer process. It is then difficult for the conventional technologies to form a pattern without increasing the memory cell array area.

### BRIEF DESCRIPTION OF THE DRAWINGS

FIG. 1 illustrates a schematic layout of a memory cell array MS of a NAND flash memory according to a first embodiment of this invention;

FIG. 2 is a I-I′ cross-sectional view along a word-line WL in FIG. 1;

FIG. 3 is a II-II′ cross-sectional view along a bit-line BL in FIG. 1;

FIG. 4 is a process chart schematically illustrating a sidewall transfer process;

FIG. 5 illustrates an example layout of a routed interconnection region of the word-line WL, a dummy word-line DWL, a drain select gate line SGD, and a source select gate line SGS of a NAND flash memory according to the first embodiment;

FIG. 6 illustrates a method for manufacturing the routed interconnection region of the word-line WL, the dummy word-line DWL, the drain select gate line SGD, and the source select gate line SGS shown in FIG. 5;

FIG. 7A illustrates a method for manufacturing the routed interconnection region of the word-line WL, the dummy word-line DWL, the drain select gate line SGD, and the source select gate line SGS shown in FIG. 5;

FIG. 7B illustrates a method for manufacturing the routed interconnection region of the word-line WL, the dummy word-line DWL, the drain select gate line SGD, and the source select gate line SGS shown in FIG. 5;

FIG. 7C illustrates a method for manufacturing the routed interconnection region of the word-line WL, the dummy word-line DWL, the drain select gate line SGD, and the source select gate line SGS shown in FIG. 5;

FIG. 8 illustrates another example layout of a routed interconnection region of a word-line WL, a dummy word-line DWL, a drain select gate line SGD, and a source select gate line SGS of a NAND flash memory according to the first embodiment described;

FIG. 9 illustrates an example layout of a routed interconnection region of a word-line WL, a dummy word-line DWL, a drain select gate line SGD, and a source select gate line SGS of a semiconductor memory device according to a second embodiment of this invention;

FIG. 10 illustrates a method for manufacturing the routed interconnection region of the word-line WL, the dummy word-line DWL, the drain select gate line SGD, and the source select gate line SGS shown in FIG. 9;

FIG. 11A illustrates a method for manufacturing the routed interconnection region of the word-line WL, the dummy word-line DWL, the drain select gate line SGD, and the source select gate line SGS shown in FIG. 9;

FIG. 11B illustrates a method for manufacturing the routed interconnection region of the word-line WL, the dummy word-line DWL, the drain select gate line SGD, and the source select gate line SGS shown in FIG. 9;

FIG. 11C illustrates a method for manufacturing the routed interconnection region of the word-line WL, the dummy word-line DWL, the drain select gate line SGD, and the source select gate line SGS shown in FIG. 9;

FIG. 12 illustrates an example layout of a routed interconnection region of a word-line WL, a dummy word-line DWL, a drain select gate line SGD, and a source select gate line SGS of a NAND flash memory according to a third embodiment of this invention;

FIG. 13 illustrates a method for manufacturing the routed interconnection region of the word-line WL, the dummy word-line DWL, the drain select gate line SGD, and the source select gate line SGS shown in FIG. 12;

FIG. 14A illustrates a method for manufacturing the routed interconnection region of the word-line WL, the dummy word-line DWL, the drain select gate line SGD, and the source select gate line SGS shown in FIG. 12;

FIG. 14B illustrates a method for manufacturing the routed interconnection region of the word-line WL, the dummy word-line DWL, the drain select gate line SGD, and the source select gate line SGS shown in FIG. 12;

FIG. 14C illustrates a method for manufacturing the routed interconnection region of the word-line WL, the dummy word-line DWL, the drain select gate line SGD, and the source select gate line SGS shown in FIG. 12;

FIG. 15 illustrates an example layout of a routed interconnection region of a word-line WL, a dummy word-line DWL, a drain select gate line SGD, and a source select gate line SGS of a NAND flash memory according to a fourth embodiment of this invention;

FIG. 16 illustrates a method for manufacturing the routed interconnection region of the word-line WL, the dummy word-line DWL, the drain select gate line SGD, and the source select gate line SGS shown in FIG. 15;

FIG. 17A illustrates a method for manufacturing the routed interconnection region of the word-line WL, the dummy word-line DWL, the drain select gate line SGD, and the source select gate line SGS shown in FIG. 15;

FIG. 17B illustrates a method for manufacturing the routed interconnection region of the word-line WL, the dummy word-line DWL, the drain select gate line SGD, and the source select gate line SGS shown in FIG. 15;

FIG. 17C illustrates a method for manufacturing the routed interconnection region of the word-line WL, the dummy word-line DWL, the drain select gate line SGD, and the source select gate line SGS shown in FIG. 15;

FIG. 18 illustrates an example layout of a routed interconnection region of a word-line WL, a dummy word-line DWL, a drain select gate line SGD, and a source select gate line SGS of a NAND flash memory according to a fifth embodiment of this invention;

FIG. 19 illustrates an example layout of a routed interconnection region of a word-line WL, a dummy word-line DWL, a drain select gate line SGD, and a source select gate line SGS of a NAND flash memory according to a sixth embodiment of this invention;

FIG. 20 illustrates a method for manufacturing the routed interconnection region of the word-line WL, the dummy word-line DWL, the drain select gate line SGD, and the source select gate line SGS shown in FIG. 19;

FIG. 21A illustrates a method for manufacturing the routed interconnection region of the word-line WL, the dummy word-line DWL, the drain select gate line SGD, and the source select gate line SGS shown in FIG. 19;

FIG. 21B illustrates a method for manufacturing the routed interconnection region of the word-line WL, the dummy word-line DWL, the drain select gate line SGD, and the source select gate line SGS shown in FIG. 19;

FIG. 21C illustrates a method for manufacturing the routed interconnection region of the word-line WL, the dummy word-line DWL, the drain select gate line SGD, and the source select gate line SGS shown in FIG. 19;

FIG. 22 illustrates an example layout of a routed interconnection region of a word-line WL, a dummy word-line DWL, a drain select gate line SGD, and a source select gate line SGS of a NAND flash memory according to a seventh embodiment of this invention.

FIG. 23 illustrates a method for manufacturing the routed interconnection region of the word-line WL, the dummy word-line DWL, the drain select gate line SGD, and the source select gate line SGS shown in FIG. 22;

FIG. 24A illustrates a method for manufacturing the routed interconnection region of the word-line WL, the dummy word-line DWL, the drain select gate line SGD, and the source select gate line SGS shown in FIG. 22;

FIG. 24B illustrates a method for manufacturing the routed interconnection region of the word-line WL, the dummy word-line DWL, the drain select gate line SGD, and the source select gate line SGS shown in FIG. 22; and

FIG. 24C illustrates a method for manufacturing the routed interconnection region of the word-line WL, the dummy word-line DWL, the drain select gate line SGD, and the source select gate line SGS shown in FIG. 22.

### DETAILED DESCRIPTION

Embodiments of a semiconductor memory device of the present invention will be described below. The semiconductor memory device includes a memory cell array. The memory cell array includes a memory string, the memory string including a plurality of memory cells connected in series in a first direction, and a select transistor connected to an end portion of the memory string. A plurality of word-lines are formed extending in a second direction perpendicular to the first direction and are commonly connected to the memory cells arranged in the second direction. A select gate line is formed extending in the second direction and is commonly connected to the select transistors arranged in the second direction.

The word-lines each have a first line width in the first direction and are arranged with a first distance therebetween. The select gate line includes a first interconnection portion in the first direction, the first interconnection portion having a second line width larger than the first line width, and a second interconnection portion extending from an end portion of the first interconnection portion, the second interconnection portion having a third line width the same as the first line width. A first word-line as the word-line adjacent to the select gate line is arranged having a second distance to the second interconnection portion, the second distance having a value of (4N+1) times the first distance (N is an integer of 1 or more).

Embodiments of the present invention will now be described in more detail with reference to the drawings.

### First Embodiment

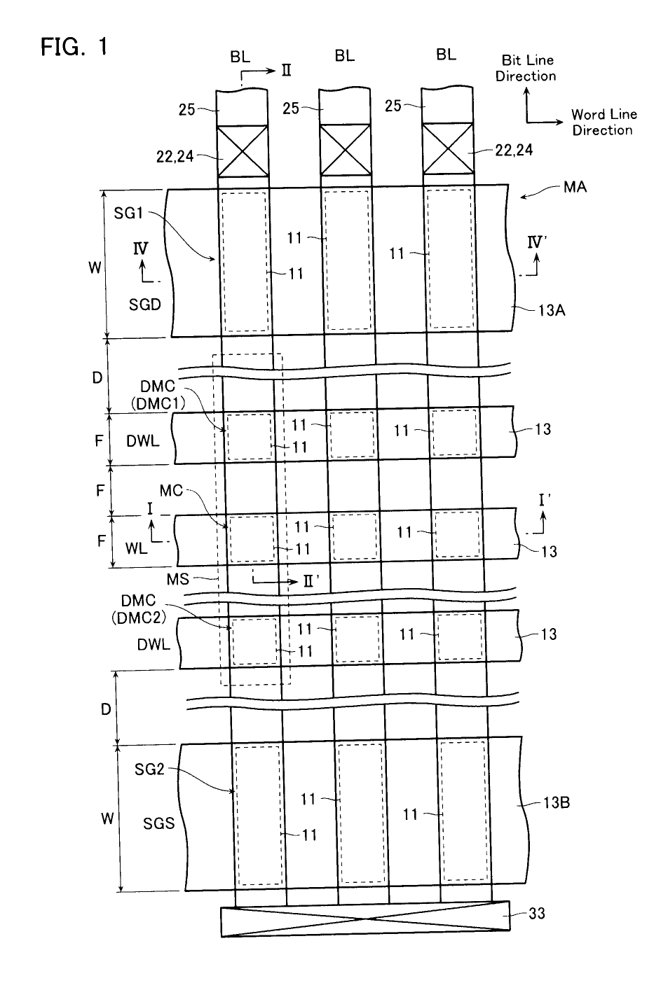

FIG. 1 illustrates a schematic layout of a memory cell array MS of a NAND flash memory according to a first embodiment of this invention. Note that in the following discussion, the direction in which the word-line WL extends is defined as “a word-line direction,” and the direction in which the bit-line BL extends is defined as “a bit-line direction.”

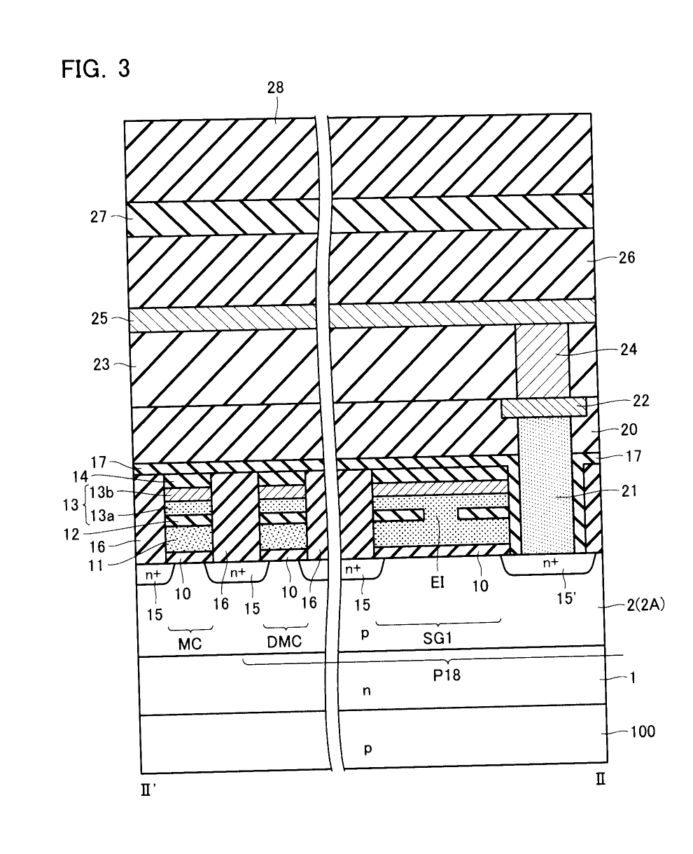

Word-lines (WL) 13 and bit-lines (BL) 25 are provided intersecting each other. At each intersection, a memory cell MC is formed. A memory cell transistor includes the memory cell MC and a source/drain diffusion layer (the reference number 15 in FIG. 3). The source/drain diffusion layer sandwiches the memory cell MC in the bit-line direction (a first direction).

A plurality of memory cells MC are arranged in the bit-line direction. The memory cells MC are connected in series via the source/drain diffusion layer 15 to form one memory string MS, as described below. Note that in this embodiment, memory cells provided at the ends of the memory string MS are dummy cells DMC, which are not used for data storage. The dummy cell DMC has a dummy word-line DWL (13) connected thereto. The dummy cell DMC has the same structure and size as the normal memory cell MC. The dummy word-line DWL is provided having the same interconnection width, interconnection distance, and interconnection pitch as the normal word-line WL. The dummy cell DMC having the same structure and size as the normal memory cell MC may make the threshold voltage of the dummy cell DMC the same as that of the memory cell MC. During the read operation or the like, for example, it is not necessary to apply a special voltage to the dummy word-line DWL, thereby stabilizing the control and reducing the possibility of misreading or the like.

In this embodiment, the word-line WL and the dummy word-line DWL are formed according to the so-called sidewall transfer process. Therefore, for the resolution limit of 2F, the word-line WL and the dummy word-line DWL each have a line width of F, for example, which is half the resolution limit. The distance between the word-lines WL and the distance between the word-line WL and the dummy word-line DWL are also F, for example.

The dummy cell DMC (DMC1) at one end (a first end portion) of the memory string MS is connected to the bit-line BL (25) via a drain-side select gate transistor SG1. The bit-line BL (25) is connected to the drain-side select gate transistor SG1 via a contact 21, a metal interconnection 22, and a contact 24.

The dummy cell DMC (DMC2) at the other end (a second end portion) of the memory string MS is connected to a not-shown source-line SL via a source-side select gate transistor SG2. The source-line SL is connected to the source-side select gate transistor SG2 via a source-side contact 33.

The gate of the drain-side select gate transistor SG1 is connected to a drain select gate line (SGD) 13A provided in parallel with the word-line WL. The gate of the source-side select gate transistor SG2 is connected to a source select gate line (SGS) 13B provided in parallel with the word-line WL.

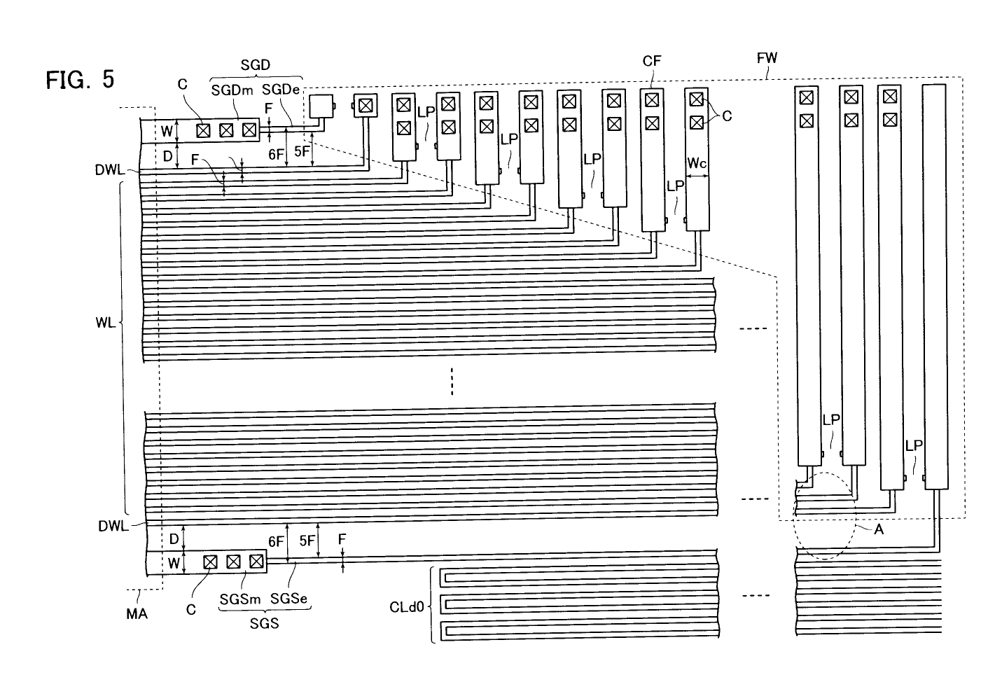

The distance D between the drain select gate line SGD and the adjacent dummy word-line DWL is larger than the above width F (D>F) . Although not shown in FIG. 1, the distance between an extended interconnection (SGDe in FIG. 5) extending from one end of the drain select gate line SGD and the adjacent dummy word-line DWL is set to 5F.

Similarly, the distance D between a source select gate line SGS and the adjacent dummy word-line DWL is larger than the width F. As described below, the distance between an extended interconnection (SGSe in FIG. 5) extending from one end of the source select gate line SGS and the adjacent dummy word-line DWL is set to 5F.

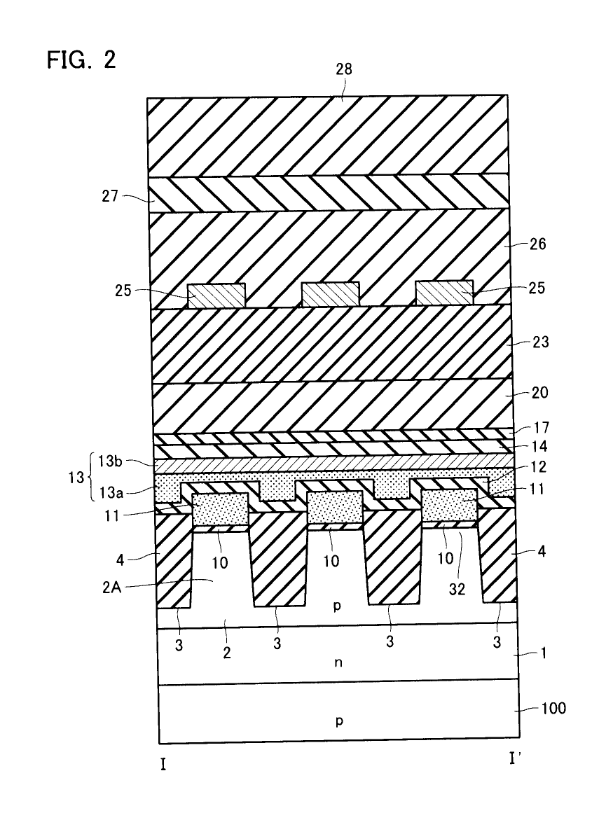

FIG. 2 is a I-I′ cross-sectional view along the word-line WL in FIG. 1. FIG. 3 is a II-II′ cross-sectional view along the bit-line BL in FIG. 1. With reference to FIG. 2, a p-type silicon substrate 100 has a cell array region thereon, in which a n-type well 1 and a p-type well 2 are formed. The p-type well 2 has trenches 3 formed at generally regular intervals therein. Each trench 3 has an element isolation insulating film 4 formed therein. In a portion of the p-type well 2 sandwiched by the element isolation insulating films 4, the memory string is formed having the memory cells MC connected in series, the drain-side select gate transistor SG1, and the source-side select gate transistor SG2. Specifically, the portion of the p-type well 2 sandwiched by the element isolation insulating films 4 functions as an element forming region 2A in which the components forming a memory cell transistor are formed such as the memory cell MC and the select gate transistors SG1 and SG2.

With reference now to FIG. 3, the configurations of the memory cell MC and the memory string MS will be described below. On the element forming region 2A, a tunnel oxide film 10 is formed, on which a floating gate 11 of a polycrystalline silicon film is formed. On the floating gate 11, an inter-gate insulation film 12 (e.g., an ONO film) is formed, on which a control gate 13 is formed. The control gate 13 includes a laminate of a polycrystalline silicon film 13a and a silicide film 13b. The silicide film 13b is formed of, for example, tungsten silicide, nickel silicide, or cobalt silicide. The control gate 13 is continuously patterned in the word-line direction as shown in FIG. 2, providing the word-line WL. Note that the same floating gate 11 and control gate 13 are also formed in the region of the select gate transistor SG1. Specifically, the select gate transistor SG1 has a gate electrode formed in the same layer as the floating gate 11, a gate electrode formed in the same layer as the control gate 13, and an inter-gate insulation film sandwiched between those gate electrodes. Note, however, that in the select gate transistor SG1, the inter-gate insulation film 12 is etched away to form an opening EI, and the floating gate 11 and the control gate 13 are short circuited via the opening EI. Although not shown in FIG. 3, the select gate transistor SG2 has a similar configuration to the transistor SG1.

The control gate 13 and the floating gate 11 are patterned at the same time using the silicon nitride film (SiN film) 14 as a mask. The patterned electrodes are used as a mask to implant n-type impurity ions to form an n-type source/drain diffusion region 15. The source/drain diffusion region 15 is shared by the adjacent memory cell transistors, thus forming the memory string MS including the memory cells MC connected in series. The memory string MS with the select gate transistors SG1 and SG2 connected to the respective ends of the memory string MS forms the NAND cell unit. On the side of the select gate transistors SG1 and SG2 opposite the memory cell transistor, a drain contact diffusion region 15′ is formed on the surface of the n-type element forming region 2A.

An interlayer insulation film 16 is embedded between the projections of the floating gate 11 and the control gate 13. A SiN film 17 is further deposited to cover the memory cell string MS.

The memory cell array MA is covered by an interlayer insulation film 20. In the interlayer insulation film 20, the contact plug 21 and the metal interconnection 22 are embedded. The metal interconnection 22 works as a first layer metal. The metal interconnection 22 may be made of tungsten, for example. The bottom surface of the contact plug 21 is connected to the n-type drain contact diffusion region 15′. Over the interlayer insulation film 20, an interlayer insulation film 23 is further laminated. In the interlayer insulation film 23, the contact plug 24 is embedded. Over the contact plug 24, the bit-line (BL) 25 such as an Al film or Cu film is formed, for example. FIG. 3 shows only the bit-line side contact portion and the interconnection 22 serves as a relay interconnection for the bit-line. The source-line SL is made of the same film as the interconnection 22.

Over the bit-line 25 is deposited an interlayer insulation film and a passivation film. The interlayer insulation film may be formed of a silicon oxide film 26 and a SiN film 27 by plasma CVD, for example. The passivation film may be formed of a polyimide film 28, for example.

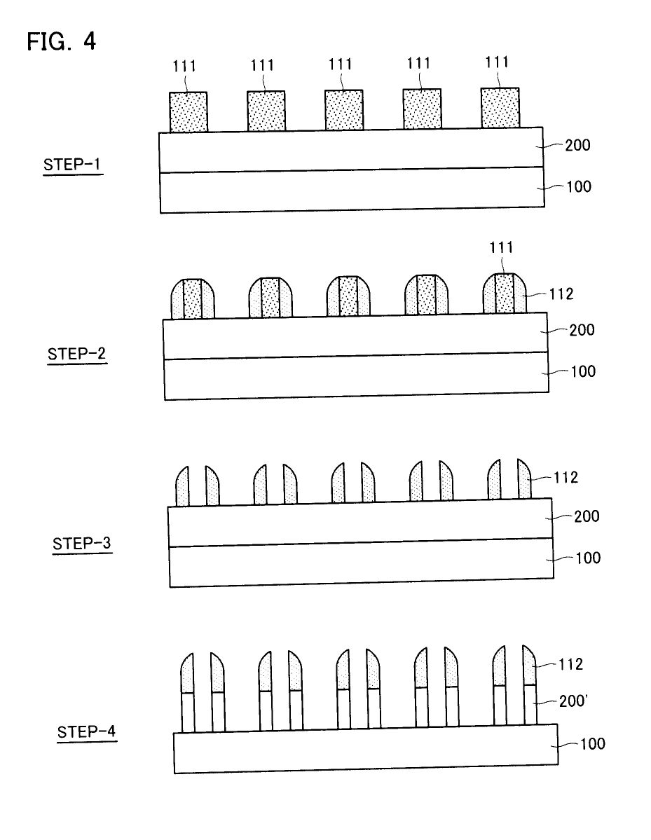

In the NAND flash memory shown in FIG. 1, some components are formed by the so-called sidewall transfer process, including the word-line WL and the dummy word-line DWL. With reference to FIG. 4, the sidewall transfer process will be outlined.

On the semiconductor substrate 100, an interconnection material 200 is deposited. The interconnection material 200 is to form an interconnection layer providing the word-line WL and the dummy word-line DWL. On the interconnection material 200, a hard mask 111 is formed.

With reference to FIG. 4, in STEP-1, the hard mask 111 is patterned into an interconnection pattern by photolithography and etching using a not-shown resist.

In STEP-2, the so-called slimming process by isotropic etching is applied to thin the width of the hard mask 111. Then, on the entire surface of the hard mask 111 including its sidewalls, a thin film is deposited. The thin film provides a sidewall film for the sidewall transfer process. The thin films deposited on the upper surface of the hard mask 11 and on the upper surface of the material film 200 are etched away using a process such as anisotropic etching. A sidewall film 112 for the sidewall transfer process is thus formed only on the sidewalls of the hard mask 111.

The hard mask 111 may include a BSG film, for example. The sidewall film 112 is made of material having a high selection ratio to the hard mask 111. For the hard mask 111 made of a BSG film, for example, the sidewall film 112 may be formed of a material such as a silicon nitride film.

In STEP-3, the hard mask 111 is removed by wet etching using an alkaline solution, leaving only the sidewall film 112, which has a high selection ratio to the hard mask 111.

In STEP-4, anisotropic etching using the sidewall film 112 as a mask etches the interconnection material 200 to form an interconnection layer 200′. The sidewall film 112 is formed as having a closed loop shape surrounding the periphery of the patterned hard mask 111. The interconnection layer 200′ is thus also formed in a closed loop shape along the sidewall film 112. The interconnection layer 200′ formed in a closed loop shape is cut at any positions thereof to be used as various interconnections. For the NAND flash memory, the closed loop shape is cut at any two positions thereof. One closed loop shape interconnection thus provides two open loop interconnections. In this way, a hard mask formed with an interconnection pitch 4F by lithography of a resolution limit 2F may provide a line-and-space pattern of an interconnection width F and an interconnection pitch 2F (a distance F).

With reference now to FIG. 5, a description is given of an example layout of a routed interconnection region of the word-line WL, the dummy word-line DWL, the drain select gate line SGD, and the source select gate line SGS.

With reference to FIG. 5, the word-line WL and the dummy word-line DWL are formed (with an interconnection pitch 2F) by the sidewall transfer process to have a width F, which is half the resolution limit 2F, and to have a distance F to the adjacent word-line WL and dummy word-line DWL.

The drain select gate line SGD and the source select gate line SGS each have a width W larger than the width F. They also each have a distance D to the adjacent dummy word-line DWL, the distance D being larger than the distance F (D>F). Additionally, the drain select gate line SGD and the source select gate line SGS include main interconnections (the first interconnection portions) SGDm and SGSm (a width W>F) and extended interconnections (the second interconnection portions) SGDe and SGSe (a width F) extending from one ends of the main interconnections SGDm and SGSm, respectively. The main interconnections SGDm and SGSm are routed on the element forming region 2A and function as the gate electrodes of the select gate transistors SG1 and SG2, respectively.

These extended interconnections SGDe and SGSe are formed by the sidewall transfer process like the word-line WL and the dummy word-line DWL. The SGDe and SGSe each have a width F smaller than the resolution limit 2F. The width F of the extended interconnections SGDe and SGSe (the second interconnection portion) is also smaller than the width W of the main interconnections SGDm and SGSm (the first interconnection portions). The SGDm and SGSm are the main portions of the select gate lines SGD and SGS, respectively. Although FIG. 5 shows that the extended interconnections SGDe and SGSe extend from near the center of the main portions of the select gate lines SGD and SGS in the word-line direction, the SGDe and SGSe may also extend from the sides of the end portions of the select gate lines SGD and SGS. Note that at a position adjacent to the extended interconnection SGSe (a position on the side opposite the side where the word-line WL is disposed), a dummy interconnection CLd0 having a width F and a distance F is formed by the sidewall transfer process. The dummy interconnection CLd0 is a closed loop interconnection. The distance between the dummy interconnection CLd0 and the adjacent extended interconnection SGSe is F. The dummy interconnection CLd0 thus formed may increase the lithography margin of the extended interconnection SGSe.

The main interconnections SGDm and SGSm are formed by a normal lithography process. Specifically, a sidewall film 112 is formed by the sidewall transfer process (STEP-3 in FIG. 4) for formation of the word-line WL, the dummy word-line DWL, and the extended interconnections SGDe and SGSe. Using the normal lithography process, a resist for etching the main portions SGDm and SGSm is formed such that it partially overlaps with the sidewall film 112. Using the resist and the sidewall film 112 as a mask, the material film 200 is etched. The main interconnections SGDm and SGSm having a width W (>F) are thus formed integral with the extended interconnections SGDe and SGSe having a width F. By forming the main interconnections SGDm and SGSm so as to overlap with the extended interconnections SGDe and SGSe formed by the sidewall transfer process, the circuit area of the routed interconnection region may be reduced, although a pattern is formed by a combination of a sidewall transfer process and a normal photolithography process. Before the cutting process of the above closed loop interconnection, the extended interconnections SGDe and SGSe form, together with the adjacent dummy word-line DWL, an interconnection of a closed loop shape.

The extended interconnections SGDe and SGSe, the word-line WL, and the dummy word-line DWL each include a folded interconnection portion FW. The portion FW is folded in one direction such as the left direction when viewed from the memory cell array MA. The extended interconnections SGDe and SGSe, the word-line WL, and the dummy word-line DWL each include a contact fringe CF at the end portion of the folded interconnection portion FW (near the folded position of the closed loop interconnection). The contact fringe CF is an interconnection portion for forming a contact C. The contact fringe CF has a larger interconnection width Wc than the extended interconnections SGDe and SGSe, the word-line WL, and the dummy word-line DWL.

As described above, the extended interconnections SGDe and SGSe, the word-line WL, and the dummy word-line DWL are formed by the sidewall transfer process. The interconnection formed by the sidewall transfer process is provided as a closed loop interconnection surrounding the periphery of a hard mask. To form the extended interconnections SGDe and SGSe, the word-line WL, and the dummy word-line DWL, therefore, a cutting process is carried out in which the resulting closed loop interconnection is cut at any position thereof.

In this embodiment, one closed loop interconnection has two contact fringes CF formed at the end portion of the folded interconnection portion FW, and the closed loop interconnection is cut at a position LP (see FIG. 5) sandwiched by the two contact fringes CF. The closed loop curve is also cut at different positions of the closed loop curve, which are not shown in FIG. 5. Note that the end portion of the cut closed loop interconnection may project from the contact fringe CF.

Before the cutting process of the closed loop interconnection, the extended interconnection SGDe extending from the drain select gate line SGD and the extended interconnection SGSe extending from the source select gate line SGS form a closed loop interconnection with the interconnection as the dummy word-line DWL. After the cutting process of the closed loop curve, the extended interconnections SGDe and SGSe become an interconnection separate from the dummy word-line DWL.

The extended interconnection SGDe has a distance of, for example, 5F to the adjacent dummy word-line DWL. This distance is five times the distance (F) between the word-lines WL or between the word-line WL and the dummy word-line DWL. This is because, in the sidewall transfer process described below, the extended interconnection SGDe and the adjacent dummy word-line DWL are formed along a groove Tr2, the groove Tr2 having a width six times the width of a groove Tr1 used for formation of the word-line WL (the width of the groove Tr2 is further enlarged by the slimming process). For similar reasons, the extended interconnection SGSe also has a distance 5F to the adjacent dummy word-line DWL. Note that the distance between the extended interconnections SGDe or SGSe and the adjacent dummy word-lines DWL is not limited to 5F, and may be (4N+1)×F (N is an integer of 1 or more). In other words, the distance may be (4N+1)(N is an integer of 1 or more) times the distance F between the word-lines WL. For example, when N=2, i.e., the distance between the extended interconnections SGDe or SGSe and the adjacent dummy word-lines DWL is 9F, the width of the groove Tr2 may be ten times the width of the groove Tr1.

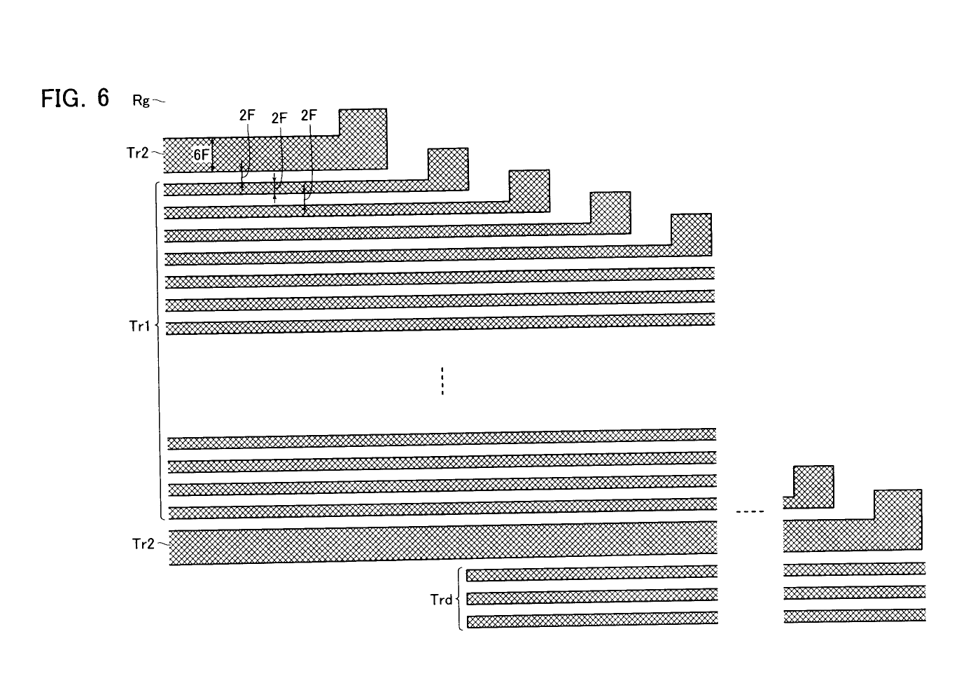

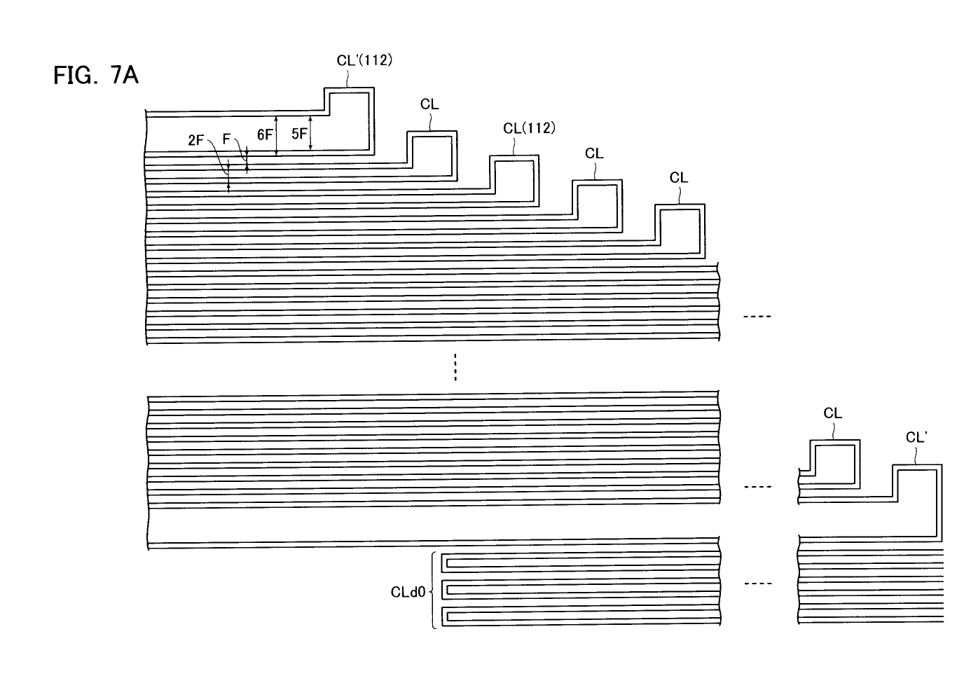

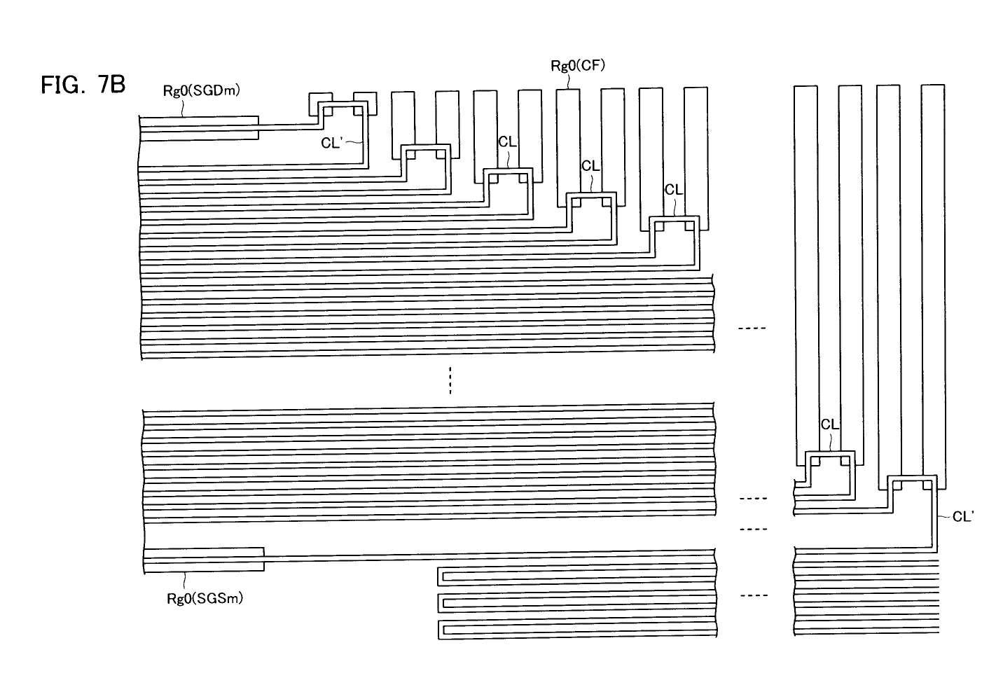

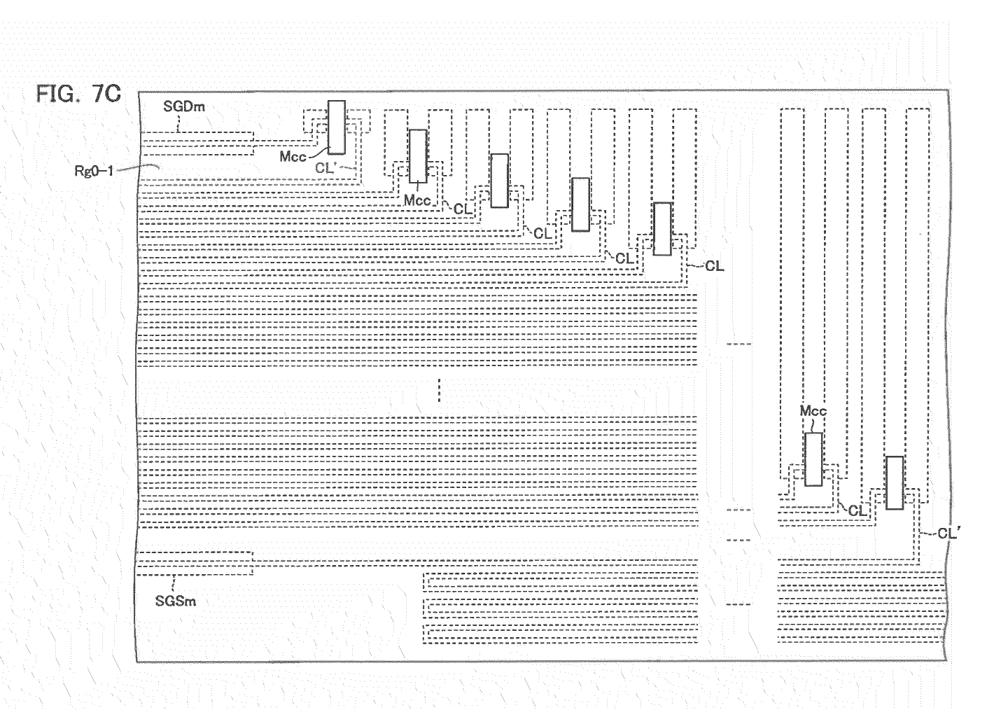

With reference now to FIG. 6 and FIG. 7A to FIG. 7C, a description is given of a method for manufacturing the routed interconnection region of the word-line WL, the dummy word-line DWL, the drain select gate line SGD, and the source select gate line SGS shown in FIG. 5. The method for manufacturing various interconnections in the memory cell array MA is similar to the conventional method, and thus the detailed description thereof is omitted here.

The material film 200 (which corresponds to 11 to 14 in FIG. 3) for the word-line WL, the dummy word-line DWL, the drain select gate line SGD, and the source select gate line SGS is formed on the entire surface of the semiconductor substrate 100. The hard mask 111 (FIG. 4) is deposited on the entire surface of the material film 200. Further, a resist Rg is deposited on the hard mask 111.

With reference to FIG. 6, the well-known photolithography and anisotropic etching are used to form the grooves Tr1 and Tr2 and a groove Trd in the resist Rg. The groove Tr1 has a width 2F and a distance 2F (i.e., a pitch corresponding to the resolution limit). The groove Tr1 is repeatedly formed along the bit-line direction. The groove Tr2 is formed on both sides of the train of the repeatedly formed grooves Tr1 with a distance 2F between the groove Tr2 and the train.

The groove Tr2 has a width 6F, which is three times the width 2F of the groove Tr1. Note that adjacent to the groove Tr2, the groove Trd is formed for assuring a sufficient lithography margin. The groove Trd has a width 2F and a distance 2F. The groove Trd is repeatedly formed in the bit-line direction.

The resist Rg is further subjected to the slimming process to increase the widths of the grooves Tr1 and Tr2. The hard mask 111 is etched using the resist Rg as a mask (the STEP-1 state in FIG. 4). Then, on the sidewalls of the hard mask 111, the sidewall film 112 (FIG. 4) is formed (the STEP-2 state in FIG. 4). The hard mask 111 is removed by anisotropic etching, leaving only the sidewall film 112 (the STEP-3 state in FIG. 4). The sidewall film 112 forms closed loop curves CL and CL′ along the inner peripheries of the grooves Tr1 and Tr2, respectively. When the closed loop curves CL form, in the bit-line direction, a line-and-space pattern with an interconnection pitch 2F (an interconnection width F and a distance F), each closed loop curve CL′ forms two interconnections each having a width F and a distance 5F therebetween.

With reference to FIG. 7B, at one end of the folded portion of each of the closed loop curves CL and CL′ of the sidewall film 112, a resist Rg0 for forming the contact fringe CF is formed by a well-known method. The resists Rg0 (SGDm) and Rg (SGSm) for forming the main interconnections SGDm and SGSm, respectively, are also formed such that they partially overlap with the closed loop curve CL′.

The sidewall film 112 forming the closed loop curve CL′ is located at the outermost periphery of the interconnection pattern. The sidewall film 112 thus has a large difference of pattern density, thereby making it likely that the shape has distortion or the like and thus causes pattern collapse. In the manufacturing method in this embodiment, however, the sidewall film 112 of the closed loop curve CL′ in which the pattern collapse is likely to occur is covered by the resist Rg0, thereby limiting generation of pattern defects due to the pattern collapse.

Note that the resist Rg0 (SGDm) for forming the main interconnection SGDm is preferably disposed at an appropriate distance from the resist Rg0 for forming the contact fringe CF. If, to prevent formation of the extended interconnection SGDe, the resist Rg0 (SGDm) for forming the main interconnection SGDm is formed to cover all of the sidewall film 112 formed at the outermost periphery of the closed loop curve CL′, the main interconnection SGDm may be too close to the contact fringe CF, thereby disturbing the regularity of the interconnection pattern of the contact fringe CL. This is because the contact fringes CF are disposed at short intervals to reduce the occupied area of the cell array. It is thus preferable that the resist Rg0 (SGDm) for forming the main interconnection SGDm does not cover all of the sidewall film 112 formed at the outermost periphery of the closed loop curve CL′, and that the resist Rg0 (SGDm) is formed at an appropriate distance from the pattern of the contact fringe CF. Even if there is a sidewall film 112 formed at the outermost periphery of the closed loop curve CL′ uncovered by the resist Rg0 (SGDm), the pattern collapse is less likely to occur if such the sidewall film 112 has a short length.

The resist Rg0 may also be used to form patterns of various transistors formed in the peripheral circuit region. So, the gate electrode patterns in the peripheral circuit region may be formed at the same time, thereby omitting processes.

The material film 200 is etched using the resist Rg0 and the sidewall film 112 as a mask. Additionally, after all resist Rg0 is removed, a resist Rg0-1 is formed having openings Mcc only at the above positions LP, as shown in FIG. 7C. The closed loop cutting process is then carried out, at the positions LP, on the closed loop curves formed by the material film 200. Thus, the word-line WL, the dummy word-line DWL, the select gate lines SGD and SGS, and the contact fringe CF are formed as shown in FIG. 5. The resist Rg0-1 is removed.

The material film 200 is formed, in a portion corresponding to the periphery of the groove Tr1, as an interconnection (the word-line WL) of a line-and-space pattern having a width F and a distance F (an interconnection pitch 2F). The material film 200 is also formed, in a portion corresponding to the periphery of the groove Tr2, as two interconnections (the dummy word-line DWL and the extended interconnection SGDe or SGSe) each having a distance 5F (a pitch 6F). The distance between the dummy word-line DWL and the extended interconnection SGDe or SGSe, which are in parallel, is thus 5F.

As described above, according to the manufacturing method of this embodiment, the word-line WL and the dummy word-line DWL each may be formed as a line-and-space pattern having a width F and a distance F.

In the conventional manufacturing method, the dummy word-line DWL is formed by the sidewall film 112 positioned outermost in the closed loop curve group. So, in the conventional manufacturing method, the dummy word-line DWL is formed by the sidewall film 112 formed at a portion having a largest difference of pattern density, making it likely that the interconnection shape has distortion. It is also difficult to match the interconnection width of the dummy word-line DWL with that of the word-line WL.

In this embodiment, the dummy word-line DWL is not formed by the sidewall film 112 positioned outermost in the closed loop curve CL′, but by the sidewall film 112 facing the closed loop curve CL. Therefore, the dummy word-line DWL is formed by the sidewall film 112 formed in a portion having a relatively small difference of pattern density. Thus, the interconnection shape may have less distortion and the interconnection width may approximately match with the word-line WL width. The normal memory cell MC and the dummy cell DMC may thus have almost the same threshold voltage by the same ion implantation process. Therefore, for example, during the read operation, a voltage applied to the dummy cell DMC may be equal to a voltage applied to the normal memory cell MC. As a result of, it is easy to control the operation of semiconductor memory device.

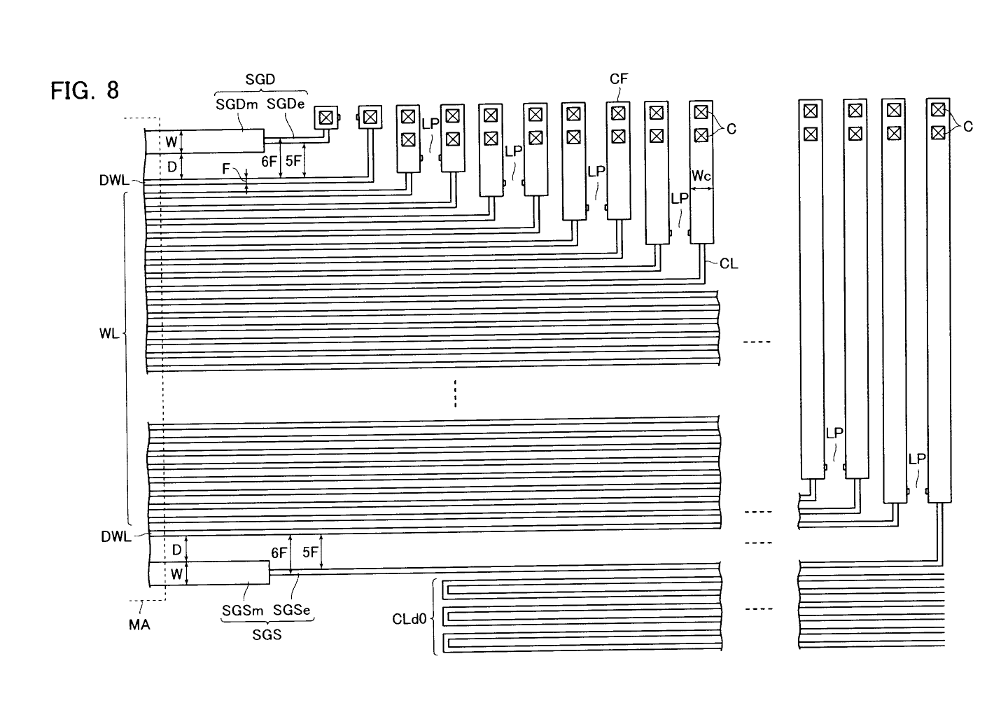

Although FIG. 5 shows that the contact C is formed in the main interconnections SGDm and SGSm of the select gate lines SGD and SGS, respectively, the contact C may also be formed in the extended interconnections SGDe and SGSe, as shown in FIG. 8. Depending on the position where the select gate line SGD is disposed in the memory cell array, one may determine, as appropriate, whether the contact C is to be arranged on the main interconnections SGDm and SGSm of the select gate lines SGD and SGS, or to be arranged on the contact fringe CF formed in the end portions of the extended interconnections SGDe and SGSe. In this way, the position of the contact C may depend on where the select gate line SGD is disposed, which may increase the degree of freedom of the layout of the upper layer interconnection.

In the conventional manufacturing method, the groove Tr1 in FIG. 6 is positioned in the outermost of the interconnection pattern. Formation of the groove Tr1 in the outermost of the interconnection pattern with the minimum exposure dimension (2F) increases the variation of the difference of interconnection pattern density. As a result, distortion arises in the shape of the outermost groove Tr1, thereby distorting the shape of the dummy word-line DWL formed by the outermost groove Tr1. To avoid the distortion, the width of the outermost groove Tr1 may be increased. This increases, however, the area of the cell array, thereby increasing the chip size.

In this embodiment, the groove Tr2 is disposed outside the outermost groove Tr1. Specifically, the existence of the groove Tr2 having a relatively large width may decrease the difference of pattern density. As a result, without increasing the width of the outermost groove Tr1, the distortion in the shape may be limited. As a result, without increasing the chip area, the distortion in the shape of the dummy word-line DWL and the word-line WL may be limited.

### Second Embodiment

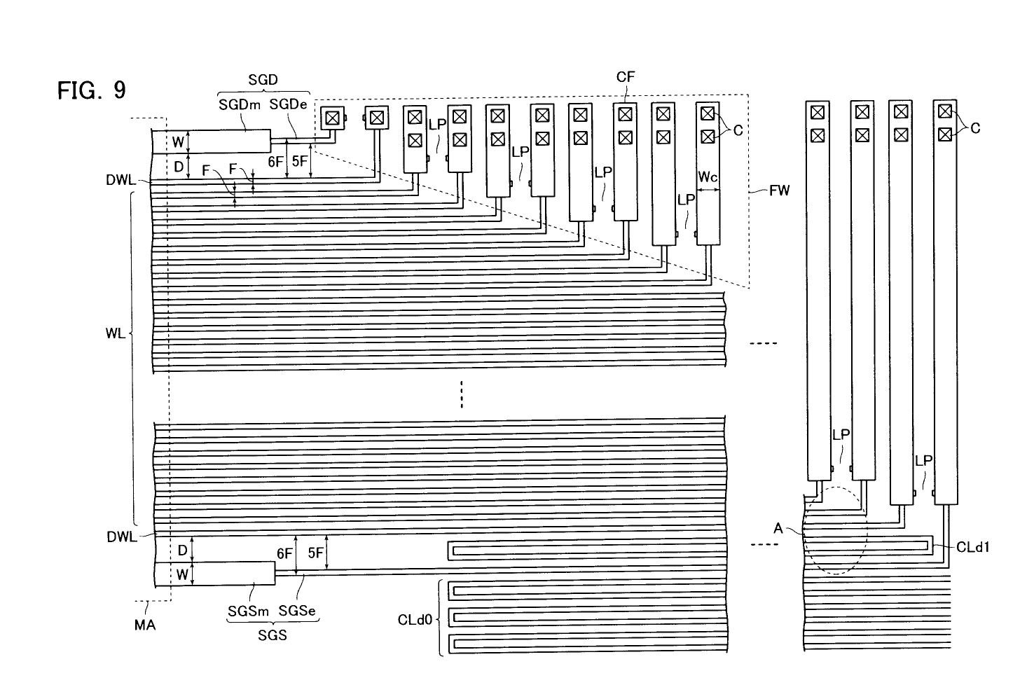

With reference now to FIG. 9, a description is given of a second embodiment of the present invention.

The structure of the memory cell array MS is similar to that of the first embodiment (FIG. 1 to FIG. 3), and thus the detailed description thereof is omitted here.

FIG. 9 illustrates an example layout of the routed interconnection region of the word-line WL, the dummy word-line DWL, the drain select gate line SGD, and the source select gate line SGS in a semiconductor memory device in the second embodiment. This layout is generally the same as the layout in the first embodiment (FIG. 5). In FIG. 9, like elements as those in FIG. 5 are designated with like reference numerals, and repeated description thereof is omitted here.

Unlike FIG. 5, between the extended interconnection SGSe in the source select gate line SGS and the adjacent dummy word-line DWL, a dummy interconnection CLd1 of a closed loop shape is formed.

Like the word-line WL, the dummy word-line DWL, and the extended interconnections SGDe and SGSe, the dummy interconnection CLd1 is an interconnection formed having a width F and a distance F (an interconnection pitch 2F). In addition, the dummy interconnection CLd1 is disposed having a distance F to the dummy interconnection DWL and the extended interconnection SGSe. Thus, the dummy interconnection CLd1 forms, together with the word-line WL, the dummy word-line DWL, the extended interconnections SGDe and SGSe, and the dummy interconnection CLd0, a line-and-space pattern having a width F and a distance F. In the first embodiment (FIG. 5), the dummy interconnection CLd1 is not provided. Near the region A surrounded by a dotted line in FIG. 5, therefore, the change of the interconnection pitch may make the interconnection width and pitch different from the assumed ones. In this embodiment, the above layout may increase the regularity of the interconnection arrangement, thereby providing a larger lithography margin.

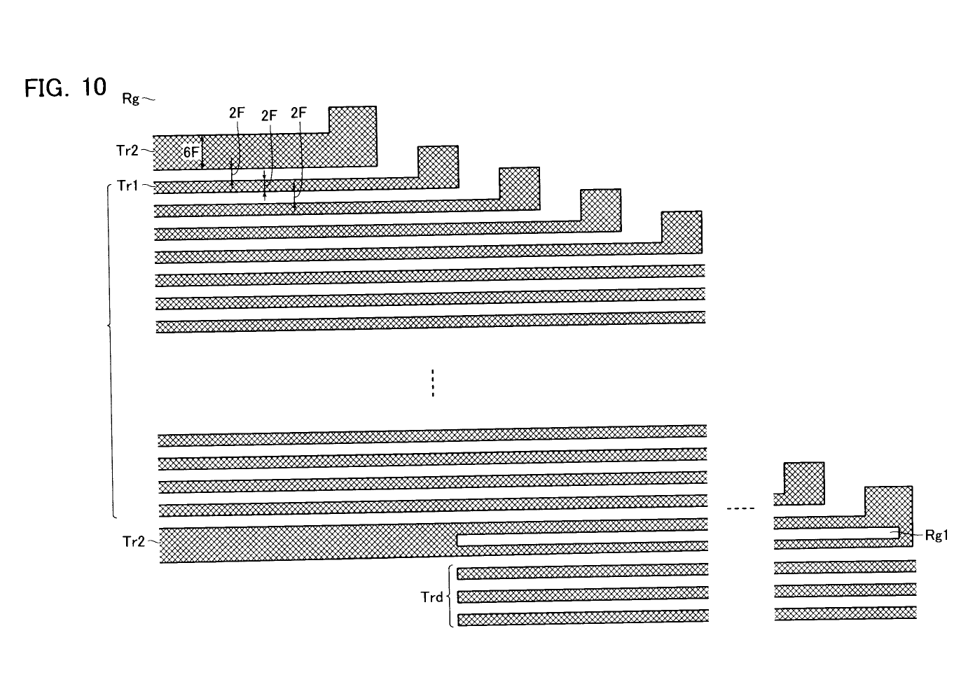

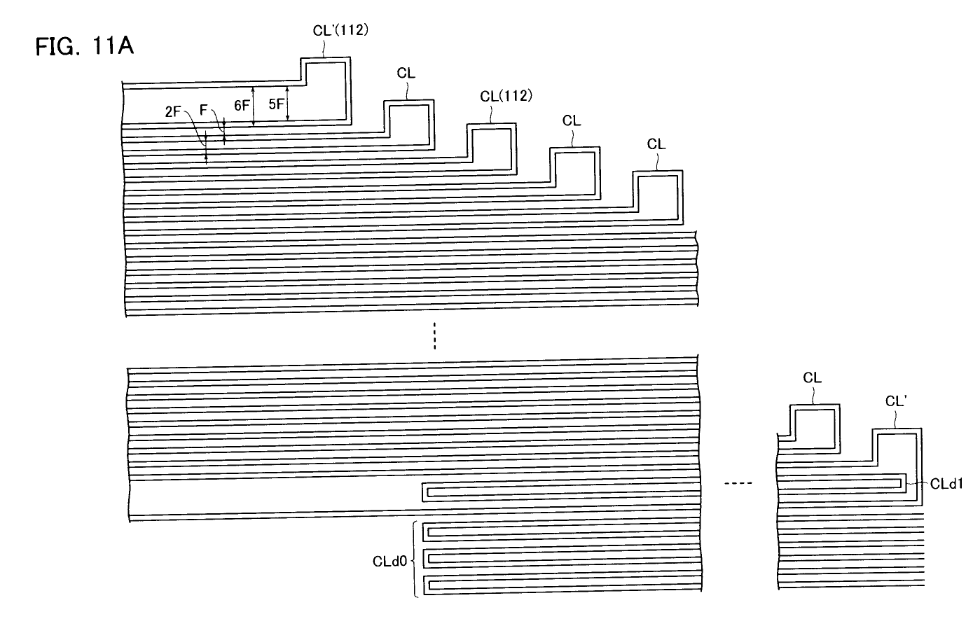

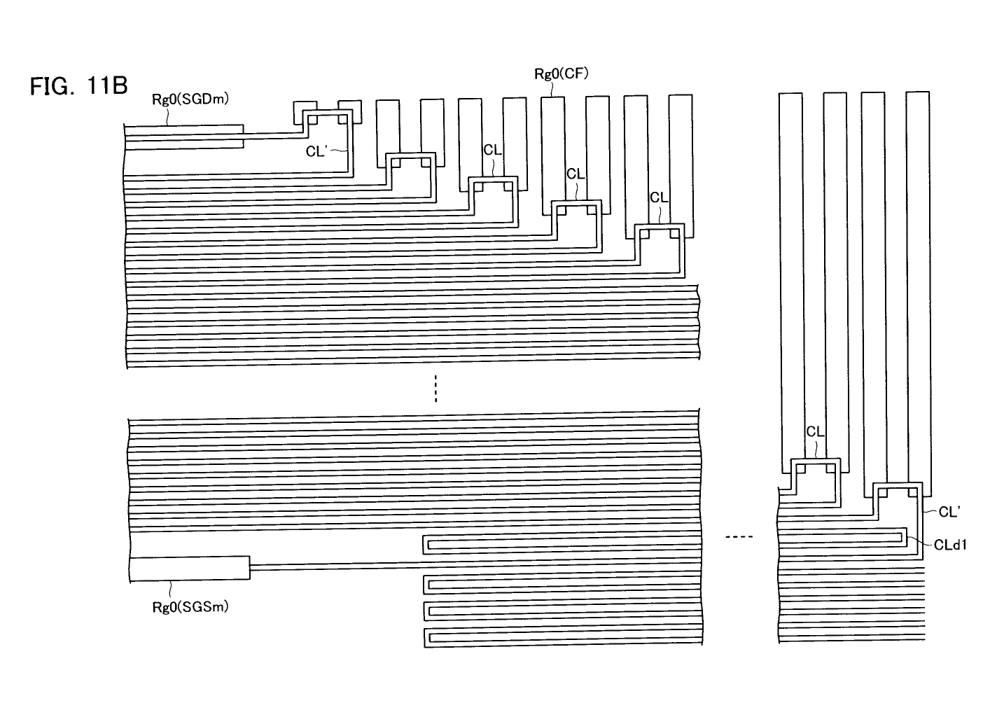

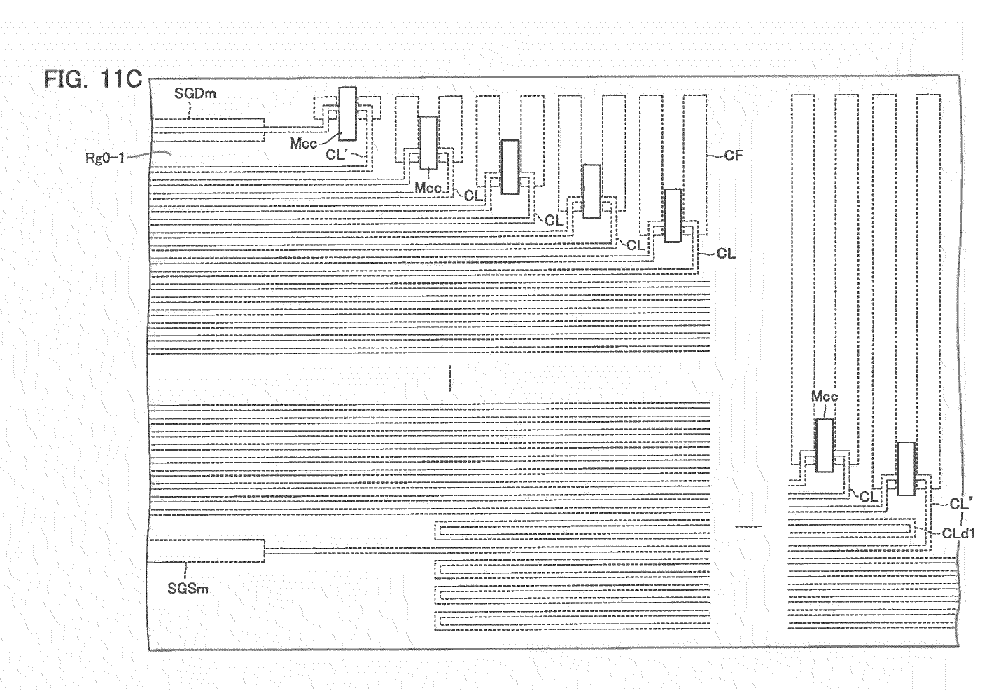

With reference now to FIG. 10 and FIG. 11A to FIG. 11C, a description is given of a method for manufacturing the routed interconnection region of the word-line WL, the dummy word-line DWL, the drain select gate line SGD, and the source select gate line SGS shown in FIG. 9. Because the method in this embodiment is generally the same as the manufacturing method in the first embodiment (FIG. 6, FIG. 7A, FIG. 7B, and FIG. 7C), only the different portions will be described below.

With reference to FIG. 10, in this second embodiment, the above dummy interconnection CLd1 is formed by leaving an island resist Rg1 in the groove Tr2 on the source select gate line SGS side.

Like the first embodiment, the following processes are carried out: the slimming process on the resist Rg (the resist Rg1 is thinned); the etching process on the hard mask 111 using the resist Rg as a mask; and the forming process of the sidewall film 112. The sidewall film 112 is thus formed, as shown in FIG. 11A, as the closed loop curves CL and CL′ along the inner peripheries of the grooves Tr1 and Tr2, respectively, and is also formed as the closed loop curve CLd1 along the periphery of the hard mask 111 corresponding to the resist Rg1.

As shown in FIG. 11B, the resist Rg0 for forming the contact fringe CF is formed and then, using the resist Rg0 and the sidewall film 112 as a mask, the material film 200 is etched. Additionally, as shown in FIG. 11C, a resist is formed having the openings Mcc only at the above positions LP and the closed loop cutting process is carried out, thereby providing the word-line WL, the dummy word-line DWL, the select gate lines SGD and SGS, and the contact fringe CF, as shown in FIG. 9.

### Third Embodiment

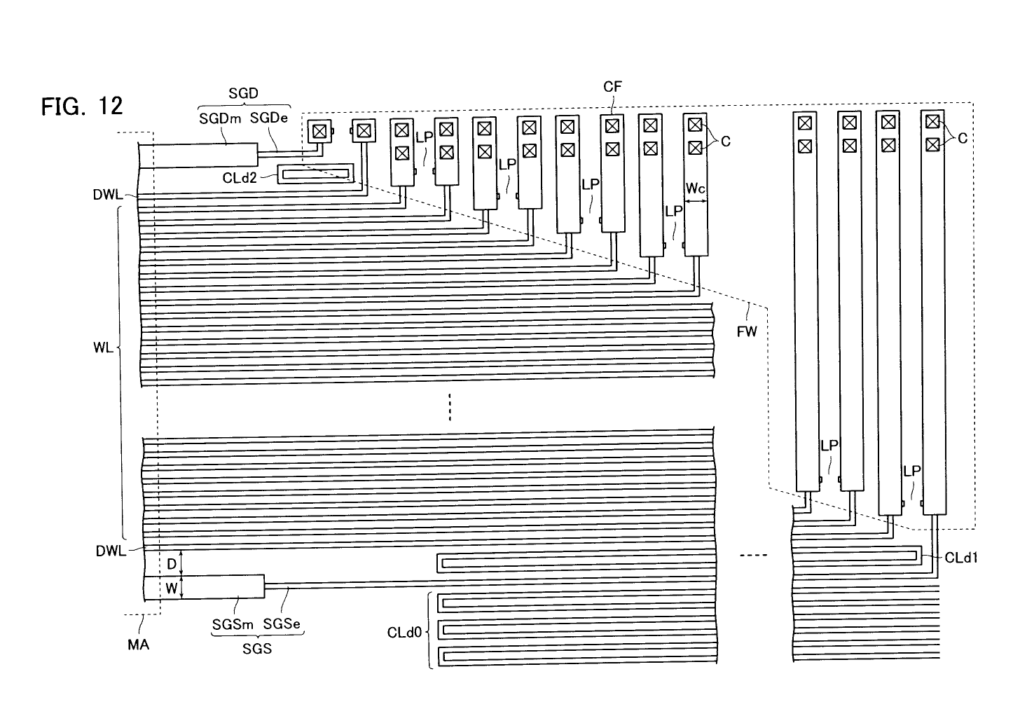

With reference now to FIG. 12, a description is given of a third embodiment of the present invention. The structure of the memory cell array MS is the same as that in the first embodiment (FIG. 1 to FIG. 3), and thus the detailed description is thereof omitted here.

FIG. 12 illustrates an example layout of the routed interconnection region of the word-line WL, the dummy word-line DWL, the drain select gate line SGD, and the source select gate line SGS in the semiconductor memory device in the third embodiment. This layout is generally the same as the layout in the second embodiment (FIG. 9). In FIG. 12, like elements as those in FIG. 9 are designated with like reference numerals, and repeated description thereof is omitted here.

Unlike FIG. 9, between the extended interconnection SGDe in the source select gate line SGD and the adjacent dummy word-line DWL, a dummy interconnection CLd2 of a closed loop shape is formed.

Like the word-line WL, the dummy word-line DWL, and the extended interconnections SGDe and SGSe, this dummy interconnection CLd2 is an interconnection formed having a width F and a distance F. In addition, the dummy interconnection CLd2 is disposed having a distance F to the dummy interconnection DWL and the extended interconnection SGDe. Thus, the dummy interconnection CLd2 forms, together with the word-line WL, the dummy word-line DWL, the extended interconnections SGDe and SGSe, and the dummy interconnection CLd0, a line-and-space pattern having a width F and a distance F. Such a layout may provide a larger lithography margin than in the above embodiments.

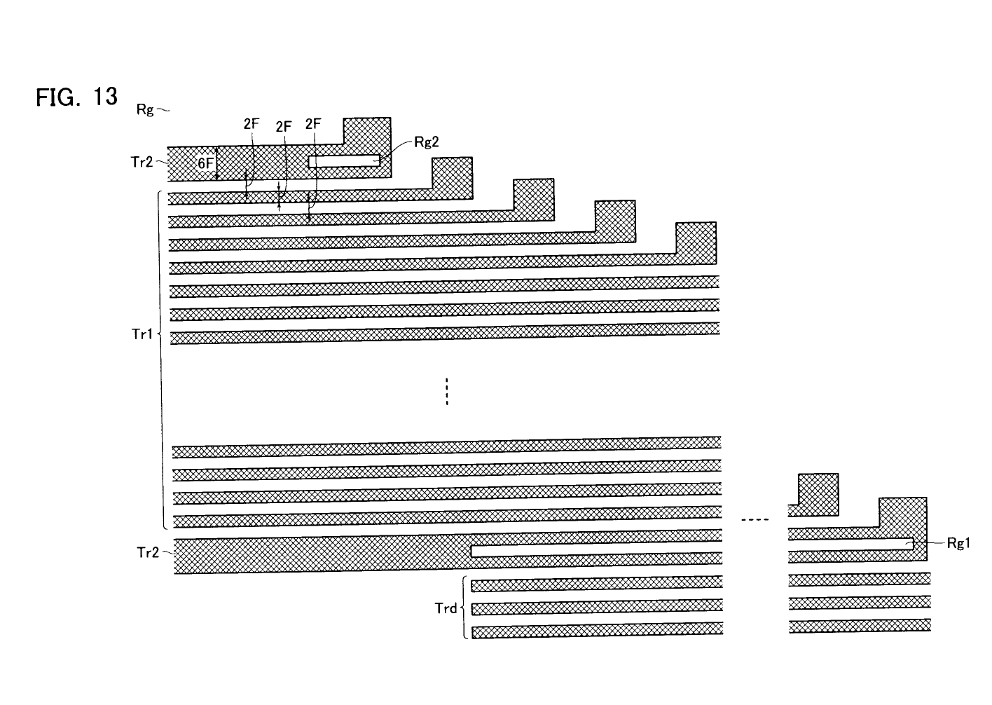

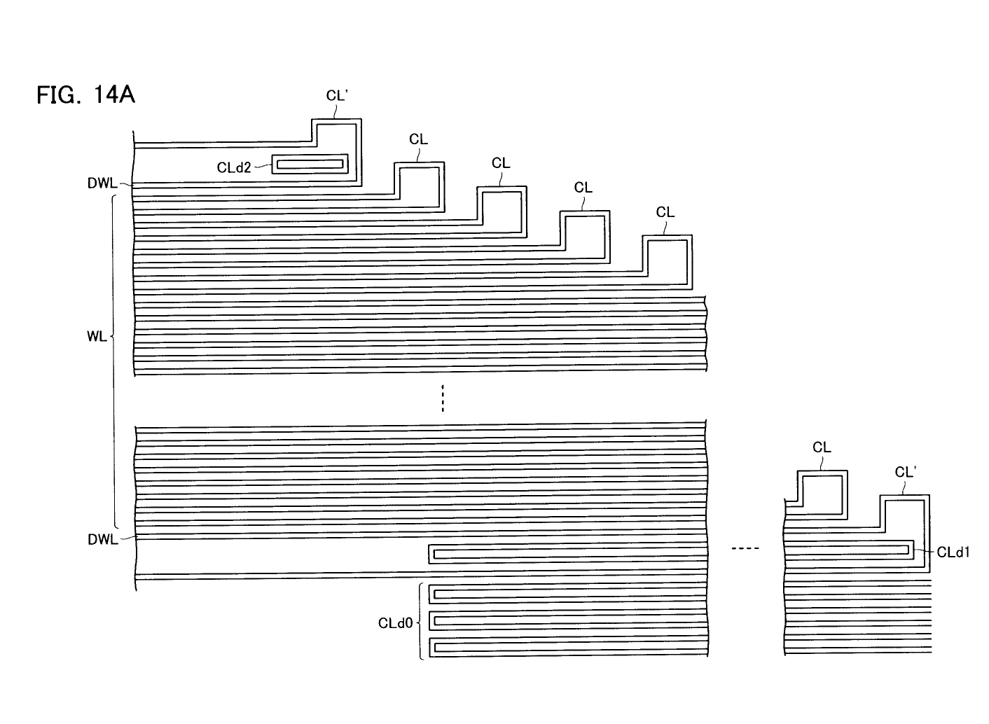

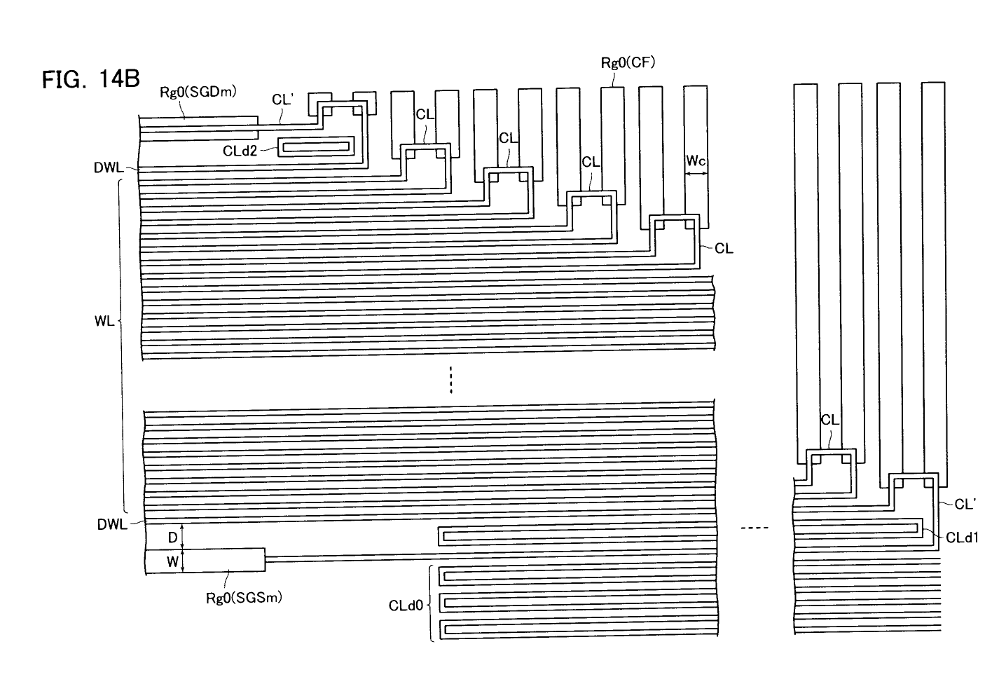

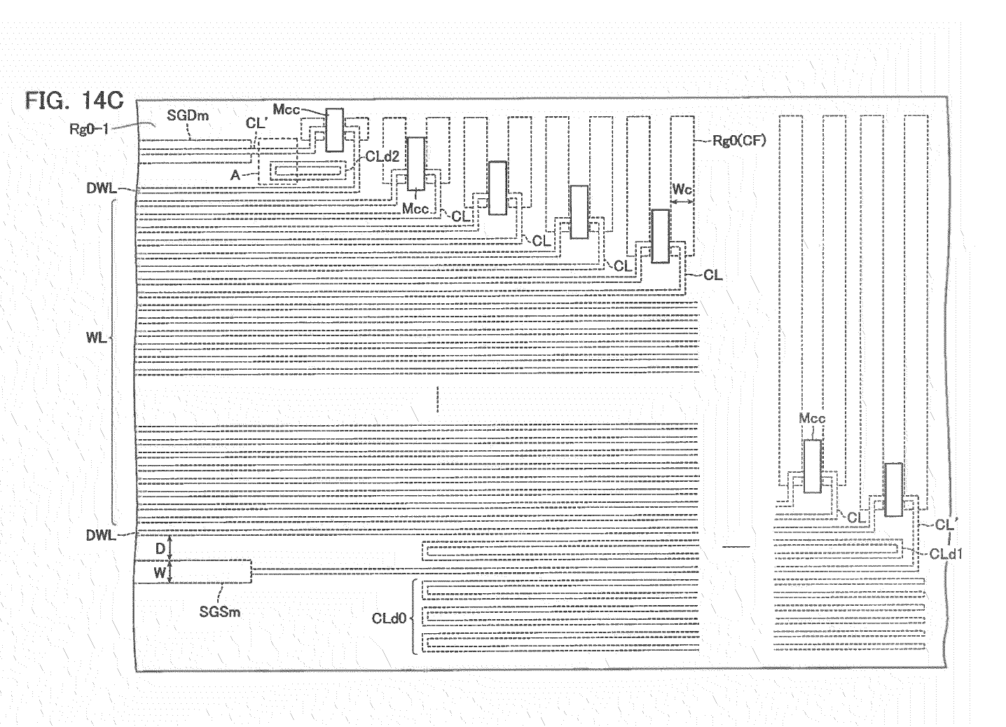

With reference now to FIG. 13 and FIG. 14 to FIG. 14C, a description is given of a method for manufacturing the routed interconnection region of the word-line WL, the dummy word-line DWL, the drain select gate line SGD, and the source select gate line SGS shown in FIG. 9. Because the method in this embodiment is generally the same as the manufacturing method in the second embodiment (FIG. 10 and FIG. 11A to FIG. 11C), only the different portions will be described below.

With reference to FIG. 13, in this third embodiment, the above dummy interconnection CLd2 is formed by leaving an island resist Rg2 in the groove Tr2 on the select gate line SGD side.

Like the above embodiments, the following processes are carried out: the slimming process on the resist Rg (the resists Rg1 and Rg2 are thinned); the etching process on the hard mask 111 using the resist Rg as a mask; and the forming process of the sidewall film 112. The sidewall film 112 is thus formed, as shown in FIG. 14A, as the closed loop curves CL and CL′ along the inner peripheries of the grooves Tr1 and Tr2, respectively, and is also formed as the closed loop curves CLd1 and CLd2 along the peripheries of the hard mask 111 corresponding to the resists Rg1 and Rg2, respectively.

As shown in FIG. 14B, the resist Rg0 for forming the contact fringe CF is formed and then, using the resist Rg0 and the sidewall film 112 as a mask, the material film 200 is etched.

If the resist Rg0 covering the main interconnections SGDm and SGSm is disposed farther from the pattern of the contact fringe CF, and the length is increased of the outermost peripheral sidewall film 112 of the closed loop curve CL′ uncovered by the resist Rg0, it is more likely that the pattern collapse of the sidewall film 112 occurs. The closed loop curve CLd2 may, however, reduce the difference of pattern density (at the point A in FIG. 14C) of the sidewall film 112 formed at the outermost periphery of the closed loop curve CL′ uncovered by the resist Rg0. This makes it less likely that the pattern collapse of the sidewall film 112 occurs.

Additionally, as shown in FIG. 14C, the resist Rg0-1 is formed having the openings Mcc only at the above positions LP and the closed loop cutting process is carried out at the positions LP, thereby providing the word-line WL, the dummy word-line DWL, the select gate lines SGD and SGS, and the contact fringe CF, as shown in FIG. 9.

### Fourth Embodiment

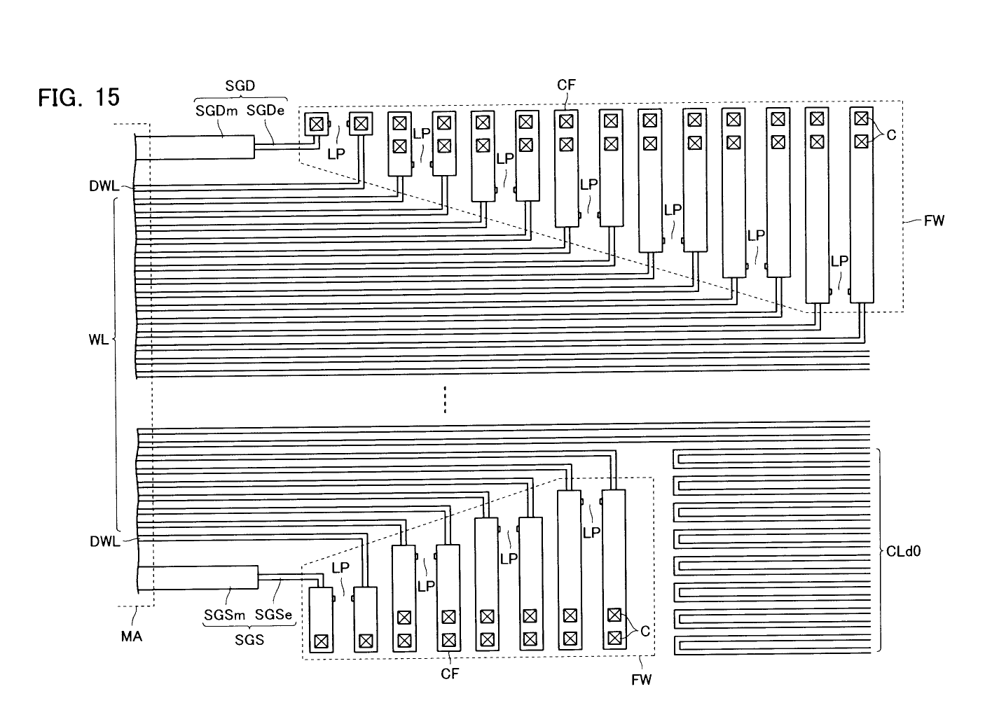

With reference now to FIG. 15, a description is given of a fourth embodiment of the present invention. The structure of the memory cell array MS is the same as that in the first embodiment (FIG. 1 to FIG. 3), and thus the detailed description is omitted here.

FIG. 15 illustrates an example layout of the routed interconnection region of the word-line WL, the dummy word-line DWL, the drain select gate line SGD, and the source select gate line SGS in the semiconductor memory device in the fourth embodiment. In this fourth embodiment, the extended interconnection SGDe, the dummy word-line DWL adjacent to the SGDe, and a part of the word-lines WL each have a folded interconnection portion FW folded to the left when viewed from the memory cell array MA, and the other word-lines WL, the extended interconnection SGSe, and the dummy word-line DWL adjacent to the SGSe each have a folded interconnection portion FW folded to the right when viewed from the memory cell array MA. In this regard, this embodiment is different from the first embodiment in which all word-lines WL, the dummy word-line DWL, and the extended interconnections SGDe and SGSe each have a shape of being folded to one direction (the left).

This shape may provide a shorter distance between the select gate line SGS and the contact fringe CF connected thereto, thereby providing a shorter length of the extended interconnection SGSe. As a result, without the dummy interconnections CLd0 and CLd1 provided outside the extended interconnection SGSe to prevent the pattern collapse of the extended interconnection SGSe, a sufficient lithography margin may be assured. Insertion of the dummy interconnection CLd1 at a distance F from the dummy word-line DWL may reduce the breakdown voltage of the select gate transistor SG2. In this embodiment, however, the possibility of the breakdown voltage reduction may be limited, while a sufficient lithography margin can be assured.

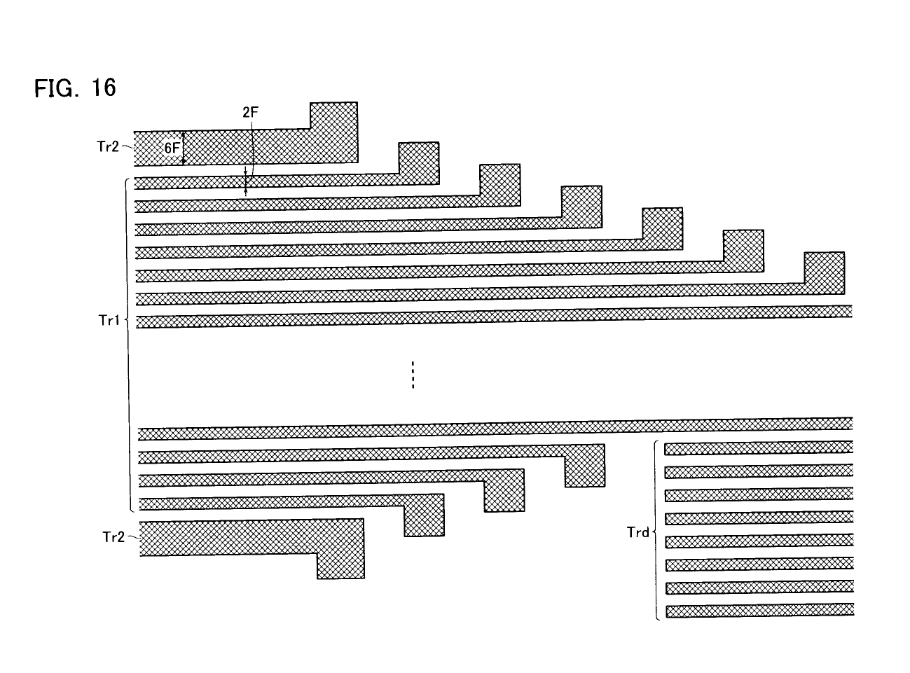

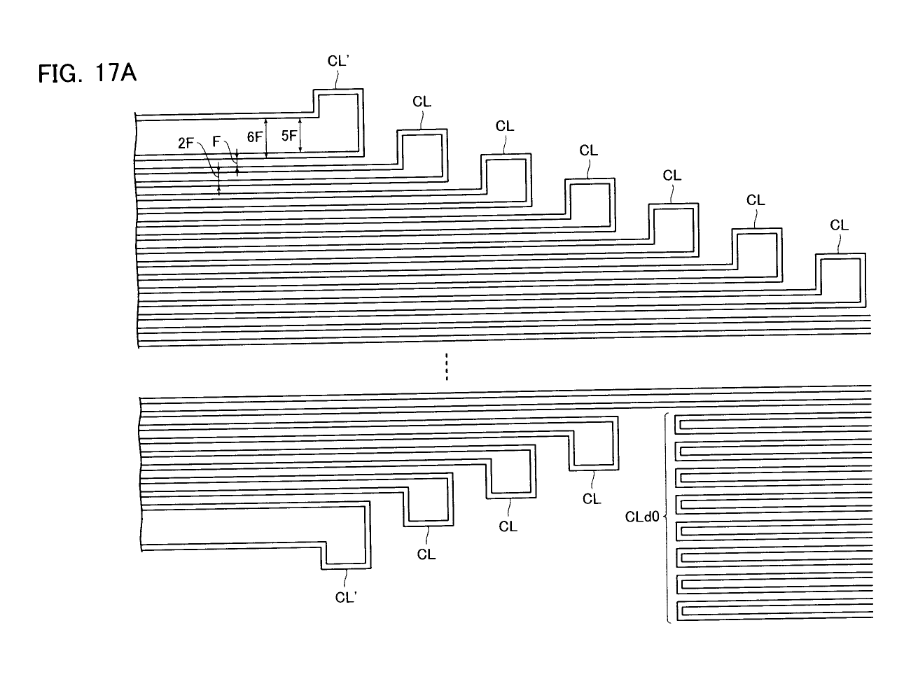

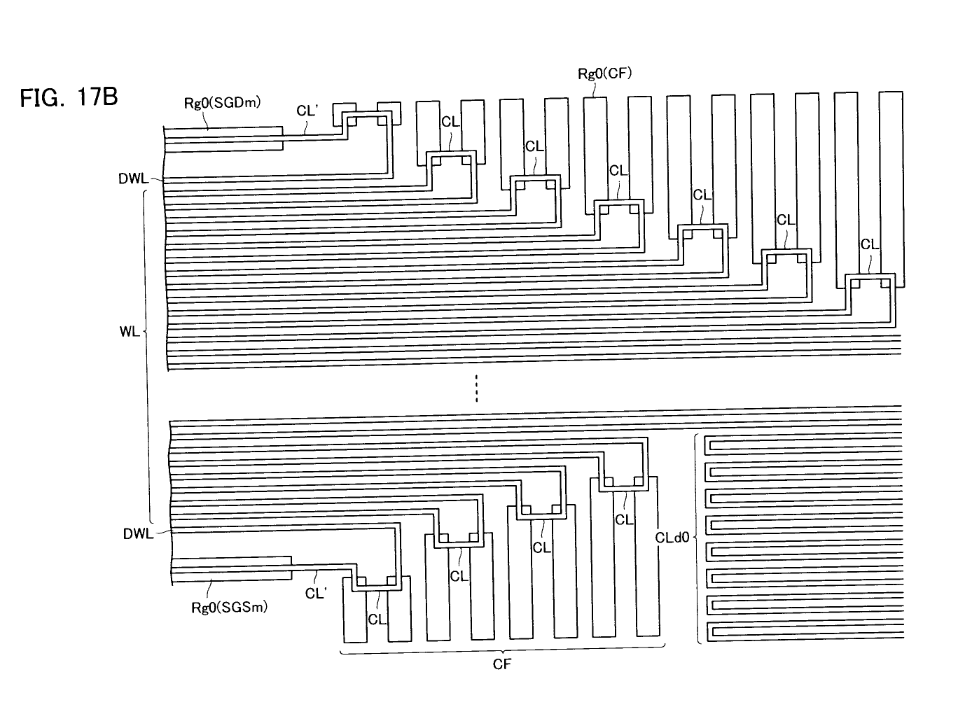

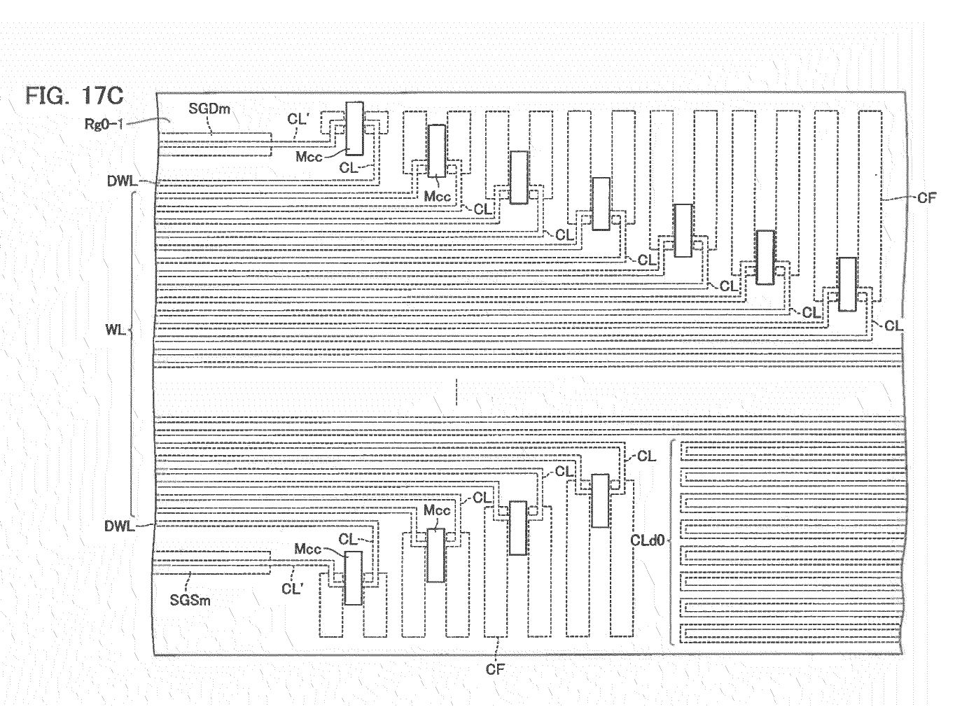

With reference now to FIG. 16 and FIG. 17A to FIG. 17C, a description is given of a method for manufacturing the routed interconnection region of the word-line WL, the dummy word-line DWL, the drain select gate line SGD, and the source select gate line SGS shown in FIG. 15. Because the method in this embodiment is generally the same as the manufacturing method in the first embodiment (FIG. 10 and FIG. 11A to FIG. 11C), only the different portions will be described below.

In conformity with the layout in FIG. 15, a part of the grooves Tr1 and Tr2 also has a folded portion folded to the left when viewed from the memory cell array MA, and the other part has a folded portion folded to the right. Otherwise, the fourth embodiment is similar to the first embodiment.

### Fifth Embodiment

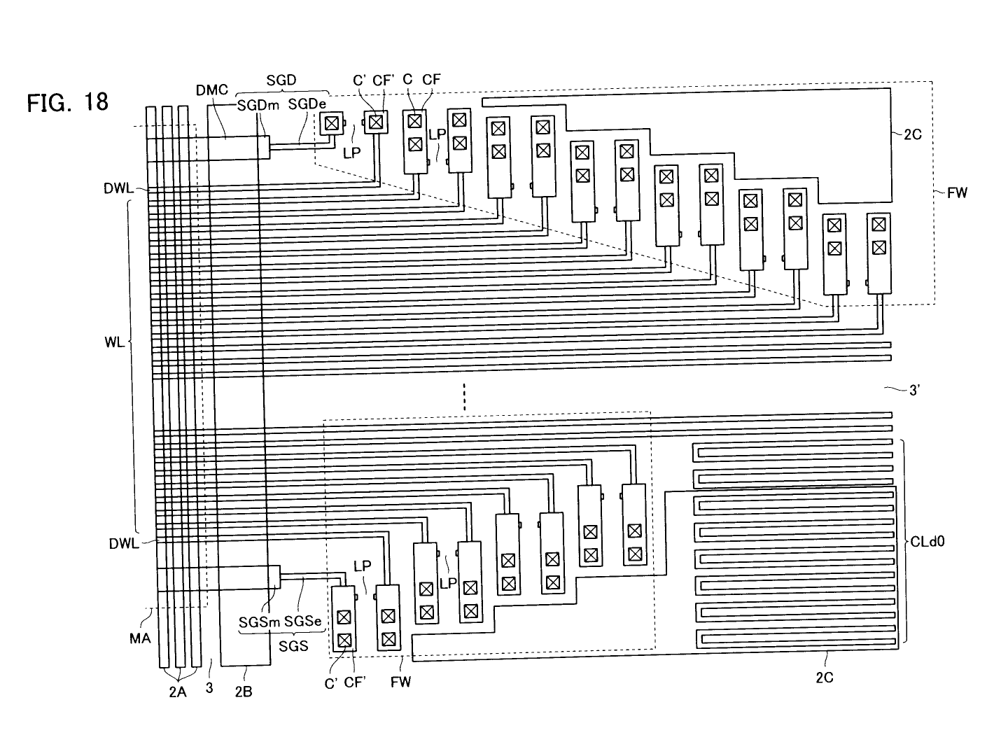

With reference now to FIG. 18, a description is given of a fifth embodiment of the present invention. The structure of the memory cell array MS is the same as that in the first embodiment (FIG. 1 to FIG. 3), and thus the detailed description thereof is omitted here.

FIG. 18 illustrates an example layout of the routed interconnection region of the word-line WL, the dummy word-line DWL, the drain select gate line SGD, and the source select gate line SGS in the semiconductor memory device in the fifth embodiment. Like the fourth embodiment, this fifth embodiment includes the two types of interconnections: a first type of interconnections having a folded interconnection portion FW folded to the left when viewed from the memory cell array MA; and a second type of interconnections having a folded interconnection portion FW folded to the right when viewed from the memory cell array MA.

Unlike the above embodiments, however, this embodiment includes dummy element forming regions 2B and 2C in the routed interconnection region, the regions 2B and 2C having the same height as the element forming region 2A. Like the element forming region 2A, the dummy element forming region 2B is a region where the p-type well 2 is left unetched and has the original height. The dummy element forming region 2B is disposed outside the element region 2A, extends in the same direction as the element region 2A (in the bit-line direction), and has a wider width than the element region 2A. The dummy memory cells DMC are formed at the intersections between the dummy element forming region 2B and each of the word-line WL, the dummy word-line DWL, and the select gate lines SGD and SDS.

Additionally, the contact C′ is disposed in the contact fringes CF′ connected to the select gate lines SGD and SGS. This is because location of the contact C′ in the main interconnections SGDm and SGSm on the dummy element forming region 2B may cause a device break down due to damage during the contact formation. As a result, connecting the contact fringes CF to the select gate lines SGD and SGS using the extended interconnections SGDe and SGSe, respectively, may reduce the area of the cell array region, while limiting a distorted shape of the contact fringe CF.

Like the element forming region 2A, the dummy element forming region 2C is a region where the p-type well 2 is left unetched and has the original height. The existence of the p-type region 2C may prevent that the element isolation insulating film 3′ in the routed interconnection region provides partially depressed regions during the chemical mechanical polishing (CMP) and the resulting etching residuals or the like are left on the top portion of the depressed region. Additionally, in order not to form the dummy memory cell DMC, the word-line WL, the dummy WL, or the select gate lines SGD and SGS are not disposed on the dummy element forming region 2C. The closed loop curve CLd0 is disposed on the dummy element region 2C, and thus the dummy memory cell DMC is formed on the dummy element region 2C. Because, however, the closed loop curve CLd0 is in a floating state, formation of the dummy memory cell DMC in the closed loop curve CLd0 do not influence the circuit operation. Thus, the etching residual or the like in the routed interconnection region may be effectively limited, while increasing the lithography margin.

### Sixth Embodiment

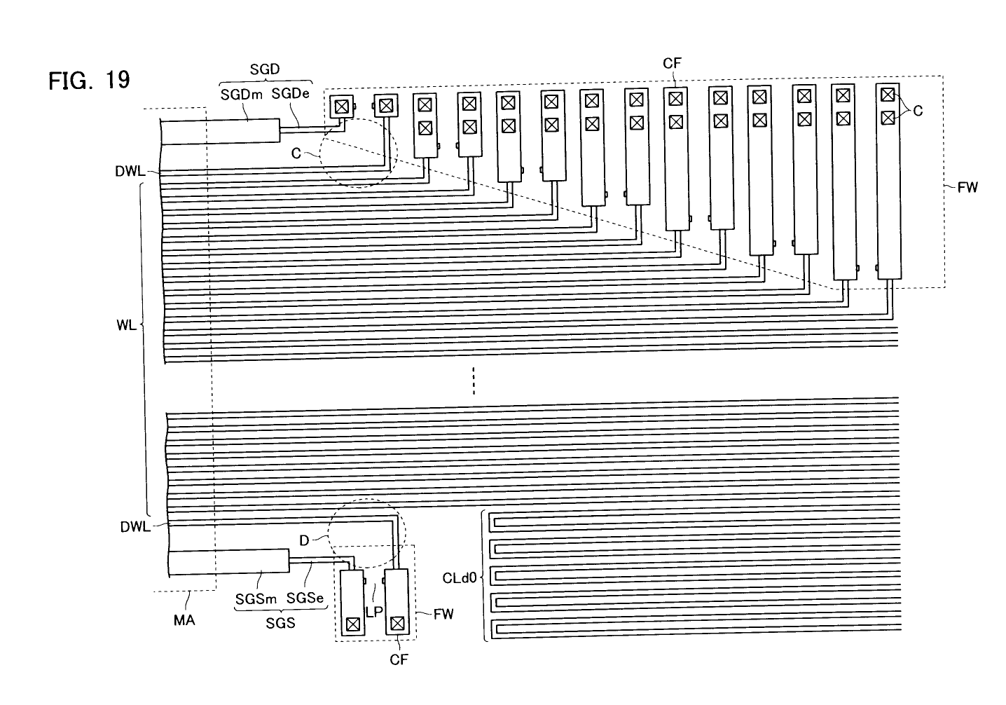

With reference now to FIG. 19, a description is given of a sixth embodiment of the present invention. The structure of the memory cell array MS is the same as that in the first embodiment (FIG. 1 to FIG. 3), and thus the detailed description thereof is omitted here.

FIG. 19 illustrates an example layout of the routed interconnection region of the word-line WL, the dummy word-line DWL, the drain select gate line SGD, and the source select gate line SGS in the semiconductor memory device in the sixth embodiment. Unlike the above embodiments, in this sixth embodiment, among the various interconnections, only the extended interconnection SGSe and the adjacent dummy word-line DWL each have a folded interconnection region FW folded to the right side when viewed from the memory cell array MA, and all of the other interconnections each have a folded interconnection region FW folded to the left side when viewed from the memory cell array MA. In this layout, although the interconnection width and distance change even in the regions C and D shown in FIG. 19, any other interconnections do not exist outside the region D, meaning that no region exists where the interconnection width and distance significantly change. This layout may thus keep a sufficiently high lithography margin.

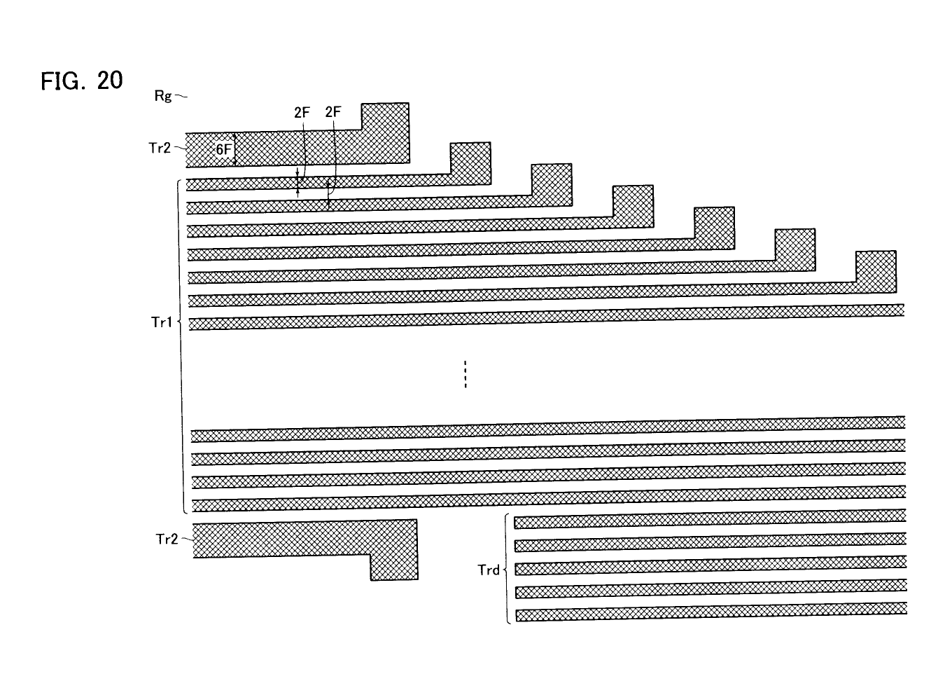

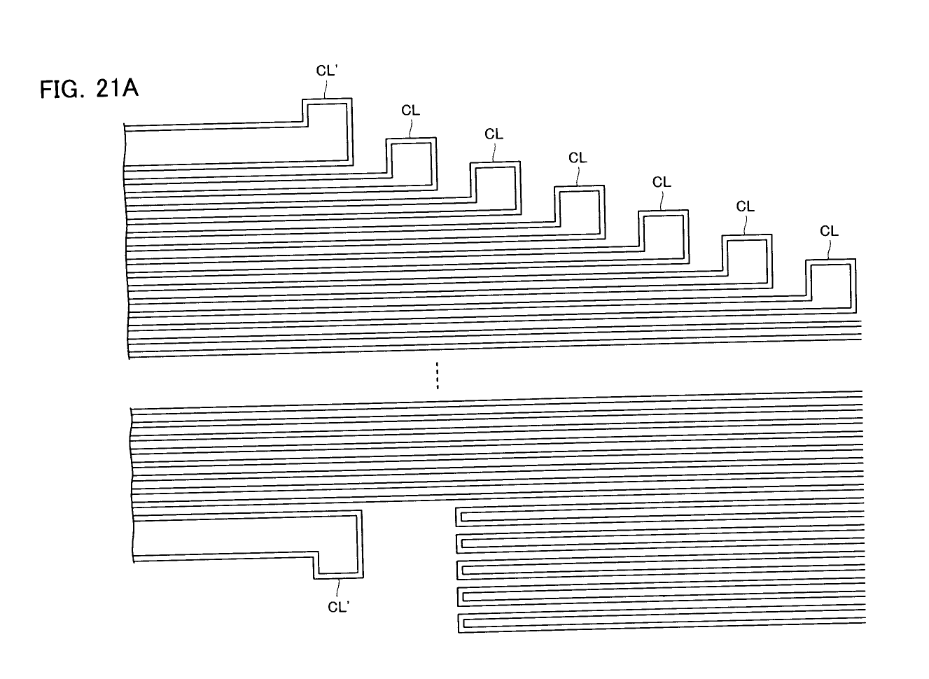

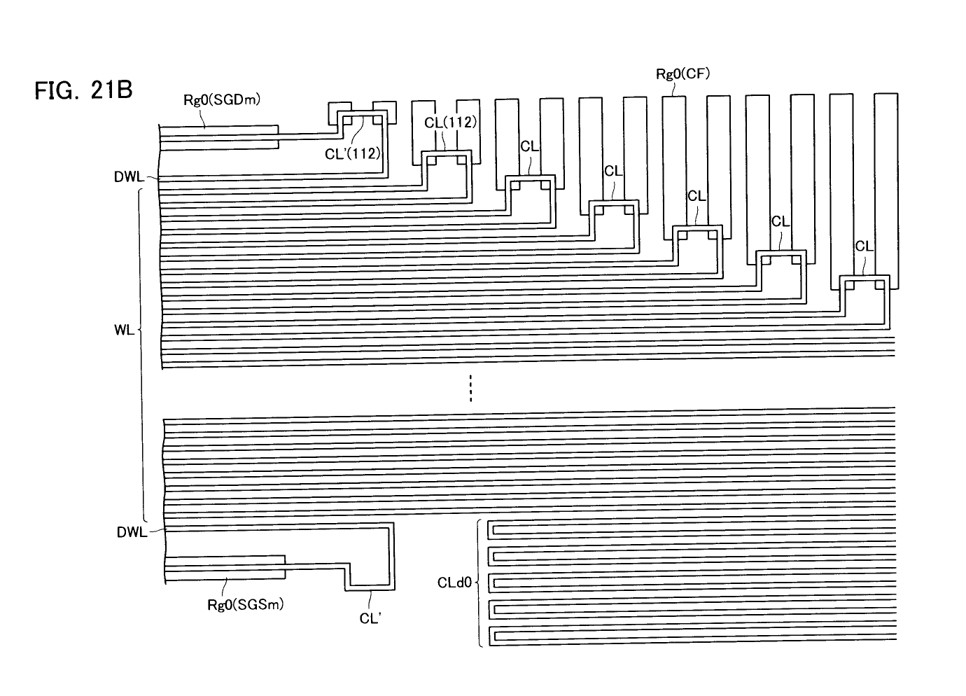

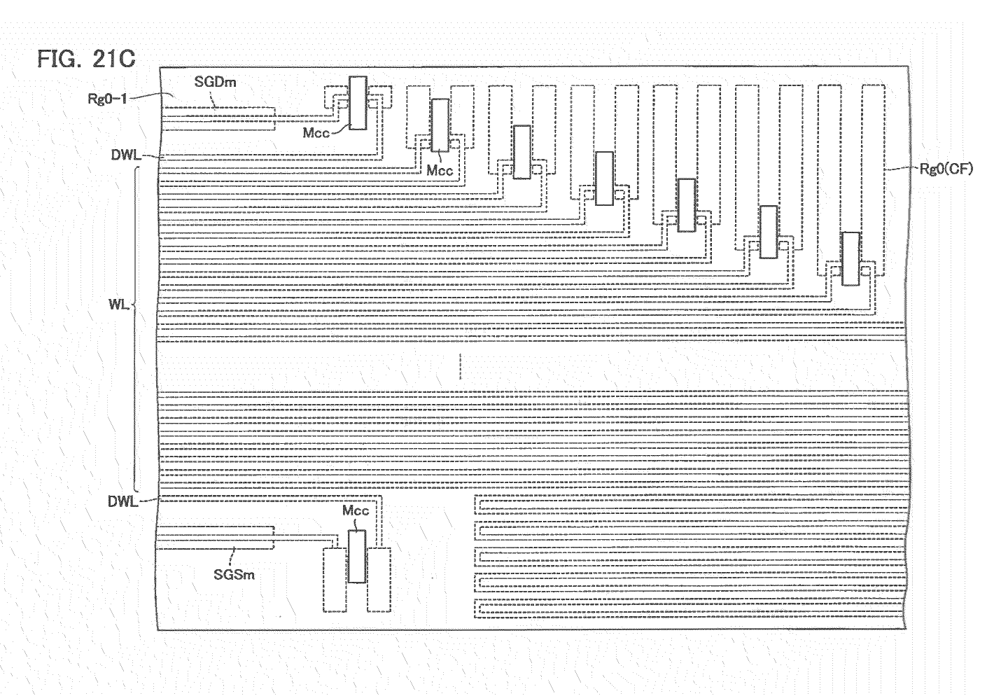

FIG. 20, FIG. 21A, FIG. 21B, and FIG. 21C illustrate a method for manufacturing the routed interconnection region of the word-line WL, the dummy word-line DWL, the drain select gate line SGD, and the source select gate line SGS shown in FIG. 19. What is different from the fifth embodiment is only the shape of the groove Tr2 for forming the extended interconnection SGSe and the adjacent dummy word-line DWL (see FIG. 20). Otherwise, this embodiment is similar to the fifth embodiment, and thus the detailed description is omitted here.

### Seventh Embodiment

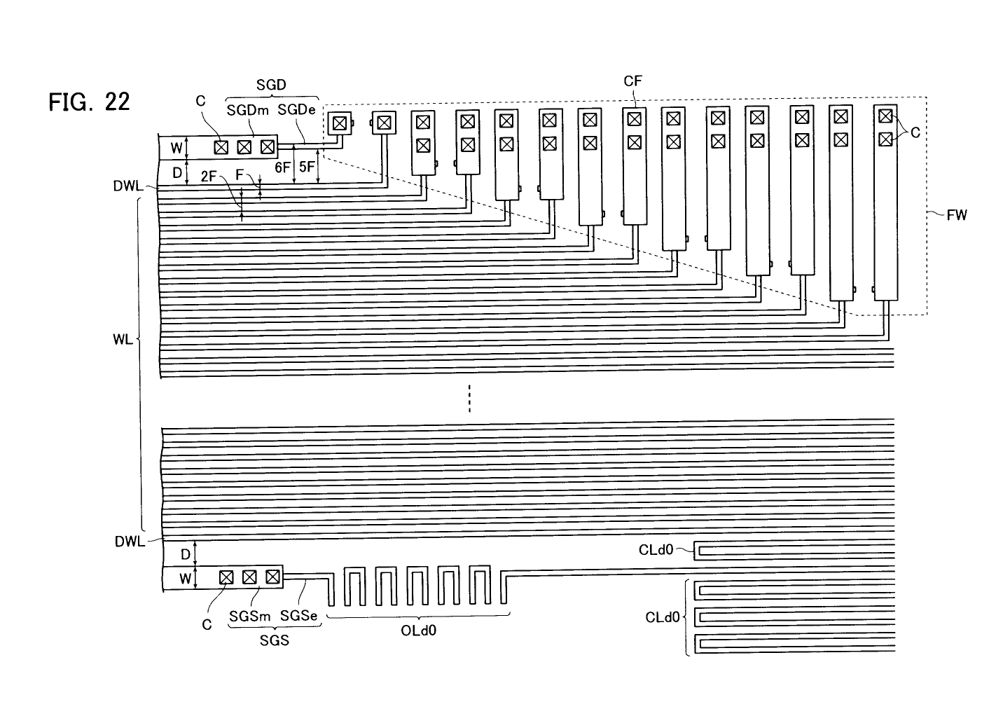

With reference now to FIG. 22, a description is given of a seventh embodiment of the present invention. The structure of the memory cell array MS is the same as that in the first embodiment (FIG. 1 to FIG. 3), and thus the detailed description thereof is omitted here.

FIG. 22 illustrates an example layout of the routed interconnection region of the word-line WL, the dummy word-line DWL, the drain select gate line SGD, and the source select gate line SGS in the semiconductor memory device in the seventh embodiment. Like the first embodiment, in this seventh embodiment, the interconnections other than the source select gate line SGS have a folded interconnection portion FW folded to the left when viewed from the memory cell array MA. The source select gate line SGS does not have a folded interconnection portion FW and the contact C is connected to the main interconnection SGSm. Additionally, in the imaginary extension of the extended interconnection SGSe, a dummy interconnection OLd0 is formed.

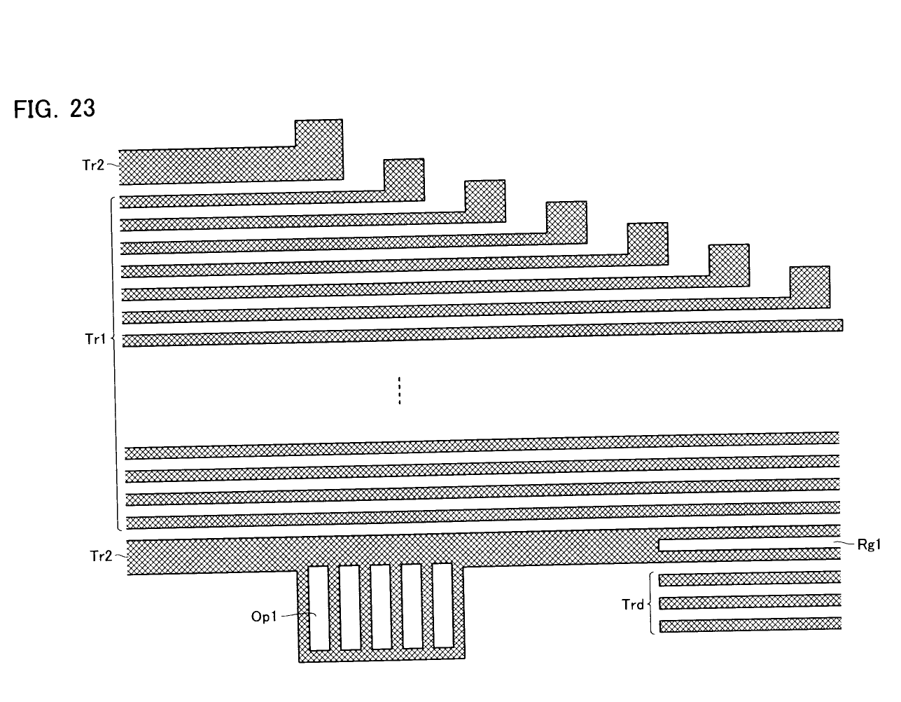

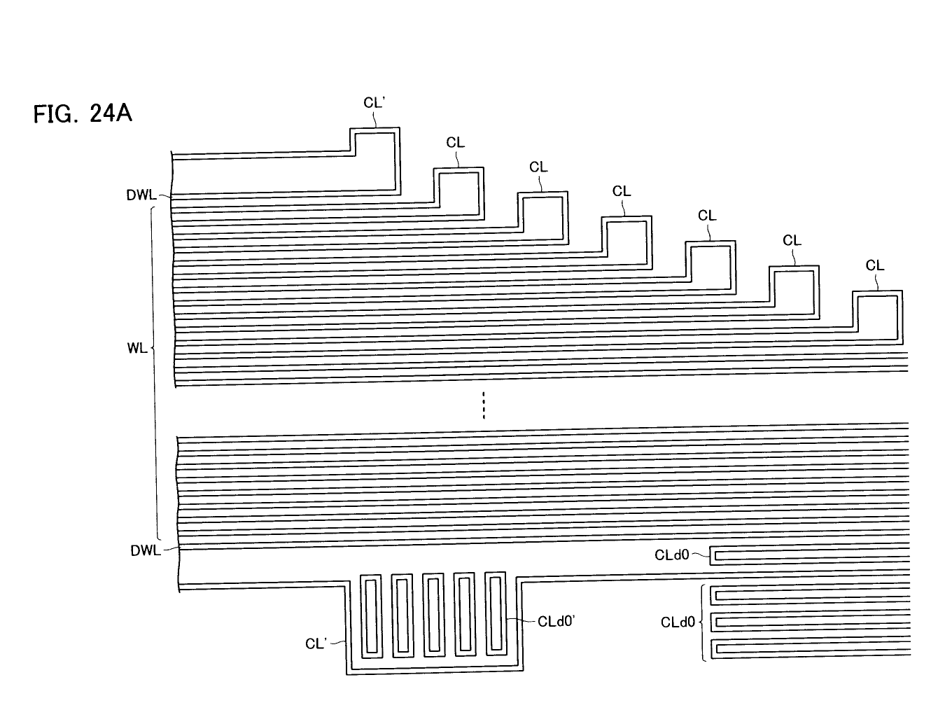

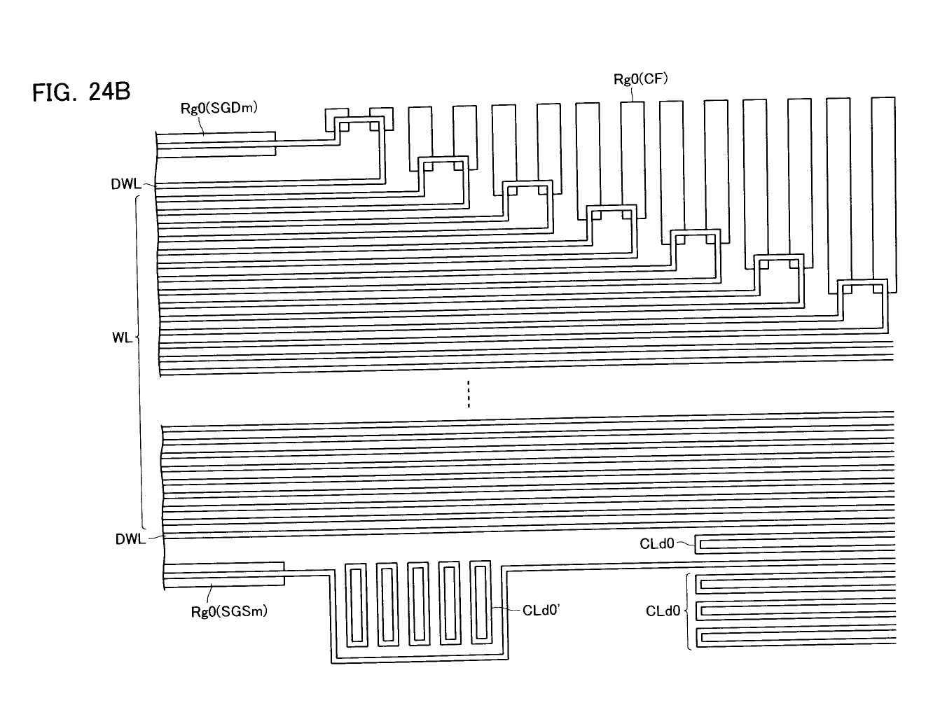

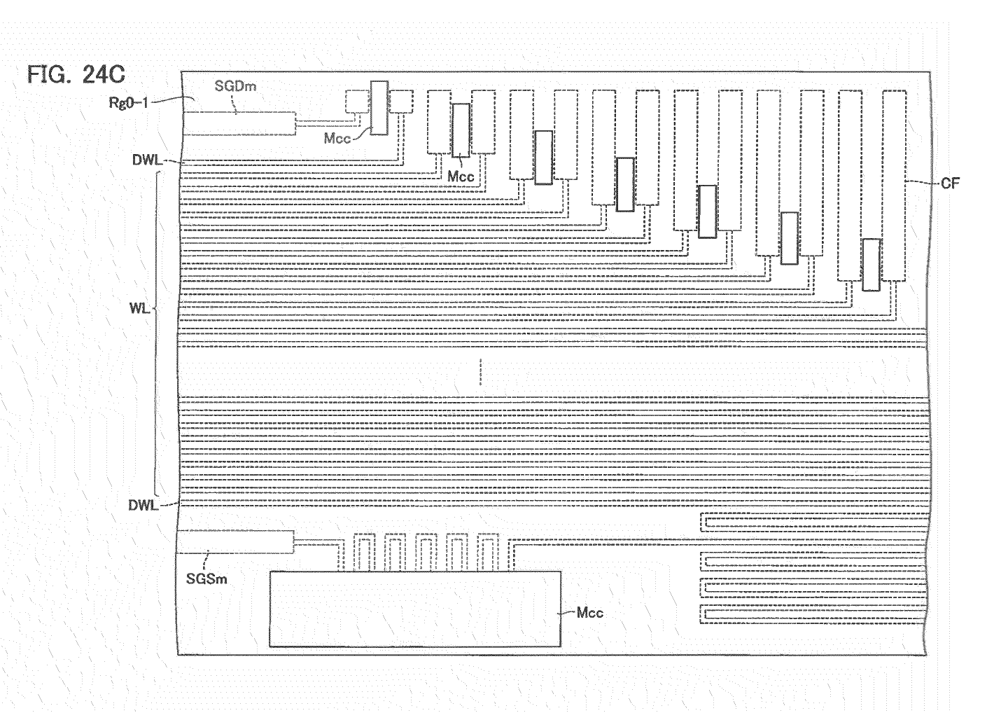

With reference now to FIG. 23 and FIG. 24A to FIG. 24C, a description is given of a method for manufacturing the routed interconnection region of the word-line WL, the dummy word-line DWL, the drain select gate line SGD, and the source select gate line SGS shown in FIG. 22. Because most of the processes are generally similar to those in the manufacturing method in the first embodiment (FIG. 6 and FIG. 7A to FIG. 7C), only the different portions will be described below.

With reference to FIG. 23, in this embodiment, the above dummy interconnection OLd0 is formed by leaving an island resist Op1 in the groove Tr2 on the select gate line SGS side.

Like the above embodiments, the following processes are carried out: the slimming process on the resist Rg (the resists Rg1 and Op1 are thinned); the etching process on the hard mask 111 using the resist Rg as a mask; and the forming process of the sidewall film 112. The sidewall film 112 is formed, as shown in FIG. 24A, as the closed loop curves CL and CL′ along the inner peripheries of the grooves Tr1 and Tr2, respectively, and is also formed as the closed loop curves CLd0 and CLd0′ along the periphery of the hard mask 111 corresponding to the resists Rg1 and Op1, respectively.

As shown in FIG. 24B, the resist Rg0 for forming the contact fringe CF is formed and then, using the resist Rg0 and the sidewall film 112 as a mask, the material film 200 is etched. As shown in FIG. 24C, a resist is formed having the openings Mcc only at the above positions LP and the closed loop interconnection CLd0′, and then a closed loop cutting process is carried out at the positions LP and the closed loop interconnection CLd0′, thereby forming the word-line WL, the dummy word-line DWL, the select gate lines SGD and SGS, and the contact fringe CF, as shown in FIG. 22.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fail within the scope and spirit of the inventions.

For example, although in the above embodiments, the memory cell adjacent to the select gate transistor is used as a dummy cell and is not used for data storage, the present invention is not limited thereto. The present invention is also applicable to a semiconductor memory device in which the memory cell adjacent to the select gate transistor is also used as a memory cell for storing effective data. More particularly, although in the above embodiments, the dummy word-line DWL is disposed adjacent to the select gate lines SGD and SGS, the normal word-line WL rather than the dummy word-line DWL may be disposed adjacent to the select gate lines SGD and SGS. This is because in the above embodiments, the dummy word-line DWL disposed adjacent to the select gate lines SGD and SGS may be modified in shape to be used as the normal word-line WL.

What is claimed is:

1. A semiconductor memory device comprising:
a memory cell array comprising a memory string, the memory string comprising a plurality of memory cells connected in series in a first direction, and a select transistor connected to an end portion of the memory string;
a plurality of word-lines formed extending in a second direction perpendicular to the first direction, the plurality of word-lines commonly connected to the memory cells arranged in the second direction; and
a select gate line formed extending in the second direction, the select gate line commonly connected to the select transistors arranged in the second direction,
the plurality of word-lines each having a first line width in the first direction, the plurality of word-lines arranged with a first distance therebetween,
the select gate line comprising,
a first interconnection portion in the first direction, the first interconnection portion having a second line width larger than the first line width, and
a second interconnection portion extending from an end portion of the first interconnection portion, the second interconnection portion having a third line width the same as the first line width.

2. The semiconductor memory device according to claim 1, wherein
a first word-line as one of the plurality of word-lines adjacent to the select gate line is arranged having a second distance to the second interconnection portion, the second distance having a value of (4N+1) times the first distance (N being an integer of 1 or more).

3. The semiconductor memory device according to claim 1, further comprising a dummy interconnection provided between the second interconnection portion and the first word-line, the dummy interconnection having a closed loop shape having a longitudinal direction in the second direction.

4. The semiconductor memory device according to claim 3, wherein
each of the second interconnection portion and the plurality of word-lines comprise: a folded interconnection portion folded and extending in the first direction; and a contact connection portion formed at the tip of the folded interconnection portion and connected to a contact.

5. The semiconductor memory device according to claim 1, wherein
one of the plurality of memory cells to which the first word-line is connected is a dummy memory cell not used for data storage.

6. The semiconductor memory device according to claim 5, wherein
each of the second interconnection portion and the plurality of word-lines comprise: a folded interconnection portion folded and extending in the first direction; and a contact connection portion formed at the tip of the folded interconnection portion and connected to a contact.

7. The semiconductor memory device according to claim 6, further comprising:
a plurality of element forming regions divided by element isolation regions, the plurality of element forming regions include a plurality of first element forming regions and a plurality of second element forming regions, each of the first element forming regions having a longitudinal direction in the first direction, the memory string being formed on each of the first element forming regions, each of the second element forming regions being formed in a routed interconnection region; and
a dummy interconnection provided between the second interconnection portion and the first word-line, the dummy interconnection having a closed loop shape having a longitudinal direction in the second direction,
the dummy interconnection being disposed on one of the second element forming region.

8. The semiconductor memory device according to claim 1, wherein
each of the second interconnection portion and the plurality of word-lines comprise: a folded interconnection portion folded and extending in the first direction; and a contact connection portion formed at the tip of the folded interconnection portion and connected to a contact.

9. The semiconductor memory device according to claim 8, further comprising:
a plurality of element forming regions divided by element isolation regions, the plurality of element forming regions include a plurality of first element forming regions and a plurality of second element forming regions, each of the first element forming regions having a longitudinal direction in the first direction, the memory string being formed on each of the first element forming regions, each of the second element forming regions being formed in a routed interconnection region; and
a dummy interconnection provided between the second interconnection portion and the first word-line, the dummy interconnection having a closed loop shape having a longitudinal direction in the second direction,
the dummy interconnection being disposed on one of the second element forming region.

10. The semiconductor memory device according to claim 1, wherein
each of the second interconnection portion and one of the plurality of word-lines adjacent to the second interconnection portion comprise: a folded interconnection portion folded and extending in the first direction; and a contact connection portion formed at the tip of the folded interconnection portion and connected to a contact.

11. The semiconductor memory device according to claim 10, wherein
a plurality of the contact connecting portions are aligned along a second direction perpendicular to the first direction.

12. A method for manufacturing a semiconductor memory device comprising a memory cell array comprising a memory string, the memory string comprising a plurality of memory cells connected in series in a first direction, a select transistor connected to an end portion of the memory string, a plurality of word-lines formed extending in a second direction perpendicular to the first direction, the plurality of word-lines commonly connected to the memory cells arranged in the second direction, and a select gate line formed extending in the second direction, the select gate line commonly connected to the select transistors arranged in the second direction,
the method comprising:
forming a material film for the plurality of word-lines and the select gate line on a semiconductor substrate and thereafter depositing a hard mask on the material film;
depositing a first resist on the hard mask;
forming a plurality of first grooves in the first resist with a first distance therebetween, each first groove having a first width and a longitudinal direction in the second direction, and forming a second groove in the first resist at the first distance from the first groove, the second groove having a second width and a longitudinal direction in the second direction;
applying a slimming process to the first resist to increase the widths of the first groove and the second groove, and thereafter etching the hard mask using the first resist as a mask;
forming a sidewall film on a sidewall of the hard mask, and thereafter etching away the hard mask;
forming a second resist, the second resist being for forming the select gate line and a contact fringe, to overlap with a closed loop curve formed by the sidewall film;
etching the material film using the sidewall film and the second resist as a mask;
forming a third resist having an opening only in a folded portion of the closed loop curve; and
performing a closed loop cutting process on the closed loop curve using the third resist as a mask.

13. The method for manufacturing a semiconductor memory device according to claim 12, wherein
the first groove and the second groove are formed to each have a folded portion folded in the first direction.

14. The method for manufacturing a semiconductor memory device according to claim 12, wherein
an island resist is left inside the second groove.

15. The method for manufacturing a semiconductor memory device according to claim 12, wherein
the second resist is formed at one end of the folded portion of the closed loop curve formed by the sidewall film.

16. A semiconductor memory device comprising:
a memory cell array comprising a memory string, the memory string comprising a plurality of memory cells connected in series in a first direction, and two select transistors connected to an end portion of the memory string;
a plurality of word-lines formed extending in a second direction perpendicular to the first direction, the plurality of word-lines commonly connected to the memory cells arranged in the second direction; and
two select gate lines formed extending in the second direction, each of the select gate lines commonly connected to the select transistors arranged in the second direction, respectively,
the plurality of word-lines each having a first line width in the first direction, the plurality of word-lines arranged with a first distance therebetween,
the select gate line comprising,
a first interconnection portion in the first direction, the first interconnection portion having a second line width larger than the first line width, and
a second interconnection portion extending from an end portion of the first interconnection portion, the second interconnection portion having a third line width the same as the first line width.

17. The semiconductor memory device according to claim 16, wherein
a first word-line as one of plurality of word lines adjacent to the select gate line is arranged having a second distance to the second interconnection portion, the second distance having a value of (4N+1) times the first distance (N being an integer of 1 or more).

18. The semiconductor memory device according to claim 16, wherein the second interconnection portion of each of the second interconnection portion bents toward a direction away from the plurality of word-lines.
